(19) United States
(12) Patent Application Publication
(10) Pub. No.: US 2026/0083012 A1
(43) Pub. Date: Mar. 19, 2026

(54) SEMICONDUCTOR DEVICE AND METHOD OF MANUFACTURING THE SAME

(71) Applicant: Renesas Electronics Corporation, Tokyo (JP)

(72) Inventors: Yasutaka NAKASHIBA, Tokyo (JP); Toshiyuki HATA, Tokyo (JP)

(21) Appl. No.: 19/269,200

(22) Filed: Jul. 15, 2025

(30) Foreign Application Priority Data
Sep. 18, 2024 (JP) 2024-161194

(51) Int. Cl. H01L 25/16; H01L 23/00; H01L 23/31; H01L 23/495; H10D 8/01; H10D 8/60; H10D 64/64

(52) U.S. Cl. CPC H10W 90/00; H10D 8/051; H10D 8/605; H10D 64/64; H10W 70/417; H10W 72/884; H10W 72/886; H10W 74/114; H10W 90/732; H10W 90/736; H10W 90/756; H10W 90/766

(57) ABSTRACT

A semiconductor chip has a first semiconductor layer, a second semiconductor layer formed on an upper surface of the first semiconductor layer, and a semiconductor region formed in the second semiconductor layer. A trench is formed in the semiconductor region. An insulating film is formed on each of an upper surface of the second semiconductor layer and an inner surface of the trench. A polysilicon film is formed on the insulating film so as to embed an inside of the trench. A front surface electrode made of metal is formed on the polysilicon electrode, and a back surface electrode made of metal is formed on a lower surface of the first semiconductor layer. An impurity concentration of the second semiconductor layer located between the semiconductor region and the first semiconductor layer is lower than an impurity concentration of each of the first semiconductor layer and the semiconductor region.

### CROSS-REFERENCE TO RELATED APPLICATIONS

The present application claims priority from Japanese Patent Application No. 2024-161194 filed on Sep. 18, 2024, the content of which is hereby incorporated by reference to this application.

### BACKGROUND

The present invention relates to a semiconductor device and a method of manufacturing the same, for example, is effectively applicable to a semiconductor device having a capacitive element and a method of manufacturing the semiconductor device.

There is a disclosed technique listed below. [Patent Document 1] Japanese Unexamined Patent Application Publication No. 2019-195013

Patent document 1 discloses a semiconductor chip on which a power transistor and a snubber capacity are formed.

### SUMMARY

When the power transistor and the snubber capacity are formed on one semiconductor chip, there is a limit to an increase in a capacitive value of the snubber capacity. Therefore, the present inventors consider not forming a snubber circuit in a power semiconductor chip including the power transistor but forming the snubber circuit on another semiconductor chip separate from the power semiconductor chip. Even when the snubber circuit is formed on the another semiconductor chip separate from the power semiconductor chip, it is desirable to improve performance of the semiconductor chip (semiconductor device) including the snubber circuit and performance of a semiconductor package (semiconductor device) using the semiconductor chip.

Other problems and novel features will be apparent from the descriptions of the present specification and the accompanying drawings.

According to one embodiment, a semiconductor device has: a first semiconductor layer of a first conductivity type; a second semiconductor layer of the first conductivity type, the second semiconductor layer being formed on an upper surface of the first semiconductor layer; and a first semiconductor region of the first conductivity type, the first semiconductor region being formed in the second semiconductor layer. The semiconductor device further has: a trench formed in the first semiconductor region; a first insulating film formed on each of an upper surface of the second semiconductor layer and an inner surface of the trench; a first electrode formed on the first insulating film so as to embed an inside of the trench; and a front surface electrode formed on the first electrode; a back surface electrode formed on a lower surface of the first semiconductor layer. Each of the front surface electrode and the back surface electrode is made of metal. An impurity concentration of the second semiconductor layer located between the first semiconductor region and the first semiconductor layer is lower than an impurity concentration of each of the semiconductor layer and the first semiconductor region.

According to one embodiment, the performance of the semiconductor device can be improved.

### BRIEF DESCRIPTION OF THE DRAWINGS

FIG. 1 is a circuit diagram showing a circuit example using a semiconductor chip of a first embodiment.

FIG. 2 is a circuit diagram showing a circuit example using the semiconductor chip of the first embodiment.

FIG. 3 is a cross-sectional view schematically showing the semiconductor chip of the first embodiment.

FIG. 4 is a cross-sectional view during a manufacturing step of the semiconductor chip of the first embodiment.

FIG. 5 is a cross-sectional view during the manufacturing step of the semiconductor chip continued from FIG. 4.

FIG. 6 is a cross-sectional view during the manufacturing step of the semiconductor chip continued from FIG. 5.

FIG. 7 is a cross-sectional view during the manufacturing step of the semiconductor chip continued from FIG. 6.

FIG. 8 is a cross-sectional view during the manufacturing step of the semiconductor chip continued from FIG. 7.

FIG. 9 is a cross-sectional view during the manufacturing step of the semiconductor chip continued from FIG. 8.

FIG. 10 is a cross-sectional view during the manufacturing step of the semiconductor chip continued from FIG. 9.

FIG. 11 is a cross-sectional view during the manufacturing step of the semiconductor chip continued from FIG. 10.

FIG. 12 is a cross-sectional view during the manufacturing step of the semiconductor chip of the first embodiment.

FIG. 13 is a cross-sectional view during the manufacturing step of the semiconductor chip continued from FIG. 12.

FIG. 14 is a cross-sectional view during the manufacturing step of the semiconductor chip continued from FIG. 13.

FIG. 15 is a cross-sectional view during the manufacturing step of the semiconductor chip continued from FIG. 14.

FIG. 16 is a cross-sectional view during the manufacturing step of the semiconductor chip continued from FIG. 15.

FIG. 17 is a cross-sectional view during the manufacturing step of the semiconductor chip continued from FIG. 16.

FIG. 18 is a plan perspective view showing a semiconductor package of the first embodiment.

FIG. 19 is a cross-sectional view showing the semiconductor package of the first embodiment.

FIG. 20 is a cross-sectional view showing the semiconductor package of the first embodiment.

FIG. 21 is a plan view showing a power semiconductor chip of the first embodiment.

FIG. 22 is a cross-sectional view showing a main part of the power semiconductor chip of the first embodiment.

FIG. 23 is a partially enlarged cross-sectional view showing the semiconductor package of the first embodiment.

FIG. 24 is a partially enlarged cross-sectional view showing a modified example of the semiconductor package of the first embodiment.

FIG. 25 is a cross-sectional view schematically showing a semiconductor chip of a first consideration example.

FIG. 26 is a cross-sectional view schematically showing a semiconductor chip of a second consideration example.

FIG. 27 is a cross-sectional view schematically showing a first modified example of the semiconductor chip of the first embodiment.

FIG. 28 is a cross-sectional view schematically showing a second modified example of the semiconductor chip of the first embodiment.

FIG. 29 is a plan perspective view showing a semiconductor package of a second embodiment.

FIG. 30 is a cross-sectional view showing the semiconductor package of the second embodiment.

FIG. 31 is a plan perspective view showing a first modified example of the semiconductor package of the second embodiment.

FIG. 32 is a cross-sectional view showing the first modified example of the semiconductor package of the second embodiment.

FIG. 33 is a cross-sectional view showing a second modified example of the semiconductor package of the second embodiment.

FIG. 34 is a plan view of a power semiconductor chip applying an IPD.

### DETAILED DESCRIPTION

In the embodiments described below, the invention will be divided into and described in a plurality of sections or embodiments when required as a matter of convenience. However, these sections or embodiments are not irrelevant to each other unless otherwise stated, and the one relates to the entire or a part of the other as a modified example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle, and the number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, embodiments of the present invention will be described in detail with reference to the accompanying drawings. Note that components having the same function are denoted by the same reference characters throughout the drawings for describing the embodiments, and the repetitive description thereof will be omitted. In addition, the description of the same or similar portions is not repeated in principle unless particularly required in the following embodiments.

Also, in some drawings used in the following embodiments, hatching is omitted even in a cross-sectional view so as to make the drawings easy to see. In addition, hatching is used even in a plan view so as to make the drawings easy to see.

In addition, in the present application, a Metal Oxide Semiconductor Field Effect Transistor (MOSFET) includes not only a MOSFET using an oxide film as a gate insulating film but also a MOSFET using an insulating film other than the oxide film as the gate insulating film.

### First Embodiment

### <Circuit Configuration>

FIG. 1 is a circuit diagram showing a circuit example using a semiconductor chip CP of the present embodiment.

A circuit shown by FIG. 1 has a power MOSFET 1, a snubber circuit 2, and a body diode 3. Between a terminal TEL and a terminal TE2, the power MOSFET 1 and the snubber circuit (RC snubber circuit) 2 and the body diode 3 are connected in parallel. The snubber circuit 2 is configured by a capacitor (capacitive element, snubber capacitor) 2a and a resistance (resistance element, snubber resistance) 2b that are connected in series. The snubber circuit 2 is formed by a semiconductor chip CP described later. The power MOSFET 1 and the body diode 3 are formed by a power semiconductor PC described later.

Specifically, a drain D1 of the power MOSFET 1 is connected to the terminal TE1, and a source S1 of the power MOSFET 1 is connected to the terminal TE2. One electrode of two electrodes (capacitor electrodes) configurating the capacitor 2a is connected to the source S1 of the power MOSFET 1, and the other electrode is connected to the drain D1 of the power MOSFET 1 via the resistance 2b. The body diode 3 is a diode parasitically formed due to a device structure of the power MOSFET 1.

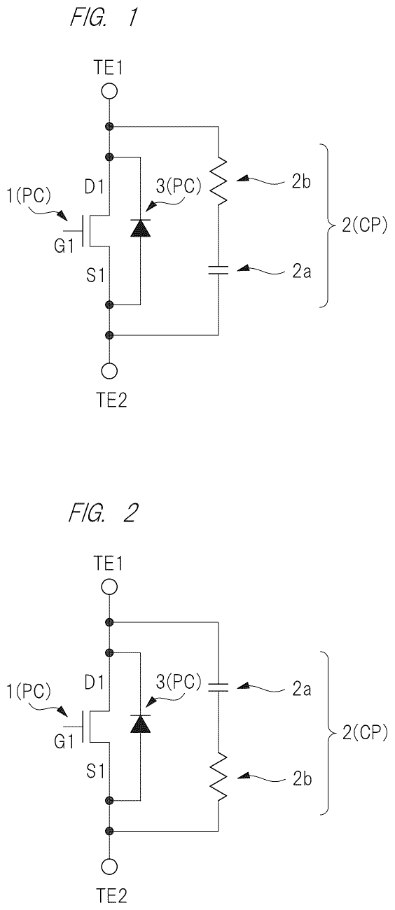

In the circuit shown by FIG. 1, positions of the capacitor 2a and the resistance 2b may be replaced, but a circuit diagram of such a case is shown by FIG. 2. In a circuit shown by FIG. 2, one electrode of two electrodes (capacitor electrodes) configurating the capacitor 2a is connected to the drain D1 of the power MOSFET 1, and the other electrode is connected to the source S1 of the power MOSFET 2 via the resistance 2b.

By applying a gate voltage, which is equal to or more than a threshold voltage, to a gate G1 of the power MOSFET 1 from a control circuit (not shown), the power MOSFET 1 becomes an on-state (conductive state), and a current (drain current) flows between the source S1 and the drain D1 of the power MOSFET 1. Accordingly, the current flows between the terminal TEL and the terminal TE2 via the power MOSFET 1. When a potential of the terminal TEL is higher than a potential of the terminal TE2, the current flows into the terminal TE2 from the terminal TEL via the power MOSFET 1.

A case in which the gate voltage of the power MOSFET 1 is reduced to a voltage (for example, 0 V) lower than the threshold voltage from a voltage equal to or more than the threshold voltage (case of turn-off) is considered. In this case, the power MOSFET 1 transitions to an off-state (non-conductive state) from the on-state. When the power MOSFET 1 is turned off, no current flows in the power MOSFET 1, so that such a back electromotive force (surge voltage) as to suppress a current change rate is generated.

As shown in FIG. 1, when the power MOSFET 1 and the snubber circuit 2 are connected in parallel, electric charges accumulated in the capacitor 2a of the snubber circuit 2 are discharged if the power MOSFET 1 is turned off. Consequently, a rapid current change in turning off the power MOSFET 1 is relieved. As a result, when the power MOSFET 1 and the snubber circuit 2 are connected in parallel in comparison with a case in which the snubber circuit 2 is not connected to the power MOSEFT 1, the current change rate in turning off the power MOSFET 1 becomes small, so that magnitude of the surge voltage generated in turning off the power MOSFET 1 can be reduced. Consequently, occurrence of electromagnetic noise due to the surge voltage generated in turning off the power MOSFET 1 can be suppressed.

### <Structure of Semiconductor Chip CP>

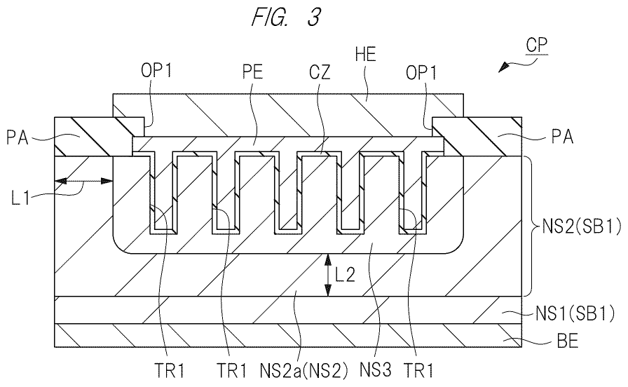

FIG. 3 is a cross-sectional view schematically showing the semiconductor chip CP of the present embodiment. The semiconductor chip CP can be regarded as the semiconductor device.

As shown in FIG. 3, the semiconductor chip (semiconductor device) CP of the present embodiment has an n-type semiconductor layer NS1, an n-type semiconductor layer NS2, an n-type semiconductor region NS3, a trench TR1, an insulating film CZ, a polysilicon electrode PE, an insulating film PA, a front surface electrode HE, and a back surface electrode BE.

The n-type semiconductor layer NS1 and the n-type semiconductor layer NS2 can be configured by a semiconductor substrate SB1. At this case, the n-type semiconductor layer NS1 and the n-type semiconductor layer NS2 are formed in the semiconductor substrate SB1. That is, the semiconductor chip CP has: the semiconductor substrate SB1 having the n-type semiconductor layer NS1, the n-type semiconductor layer NS2, and the n-type semiconductor region NS3; the trench TR1; the insulating film CZ; the polysilicon electrode PE; the insulating film PA; the front surface electrode HE; and the back surface electrode BE.

The n-type semiconductor layer (n-type semiconductor region) NS1 has an upper surface and a lower surface opposite the upper surface. A thickness of the n-type semiconductor layer NS1 is almost constant. The back surface electrode BE is formed on the lower surface of the n-type semiconductor layer NS1. The n-type semiconductor layer NS1 and the back surface electrode BE contact with each other. Specifically, the back surface electrode BE is formed on the entire lower n-type semiconductor layer NS1, and has an almost constant thickness. The back surface electrode BE is made of a metal material. Specifically, the back surface electrode BE is made of a single-layer metal film or a lamination film of a plurality of metal films. The back surface electrode BE is made of, for example, a titanium (Ti) film contacting with the n-type semiconductor layer NS1, a nickel (Ni) film on the titanium film, and a gold (Au) film on the nickel film. The back surface electrode BE is electrically connected to the n-type semiconductor layer NS1.

The n-type semiconductor layer (n-type semiconductor region) NS2 has an upper surface and a lower surface opposite the upper surface. The n-type semiconductor layer NS2 is formed on the upper surface of the n-type semiconductor layer NS1. The n-type semiconductor layer NS1 and the n-type semiconductor layer NS2 contact with each other. That is, the lower surface of the n-type semiconductor layer NS2 contacts with the upper surface of the n-type semiconductor layer NS1. The n-type semiconductor layer NS2 does not contact with the back surface electrode BE, and the n-type semiconductor layer NS1 is interposed between the n-type semiconductor layer NS2 and the back surface electrode BE. A plane dimension (plane area) of the n-type semiconductor region NS2 is the same as a plane dimension (plane area) of the n-type semiconductor layer NS1, and the n-type semiconductor layer NS2 overlaps with the n-type semiconductor layer NS1 in plan view. An outer circumference side surface of the n-type semiconductor layer NS2 aligns with an outer circumference side surfacer of the n-type semiconductor layer NS1. The outer circumference side surface of the n-type semiconductor layer NS2 and the outer circumference side surface of the n-type semiconductor layer NS1 respectively configure a part of an outer circumference side surface of the semiconductor chip CP.

Note that a case in which the plan view is mentioned about components of the semiconductor chip CP corresponds to a case of being viewed from a plane nearly parallel to the upper or lower surface of the n-type semiconductor layer NS2 or the upper or lower surface of the n-type semiconductor layer NS1.

The n-type semiconductor region (n-type semiconductor layer) NS3 is formed in the n-type semiconductor layer NS2. Specifically, the n-type semiconductor region NS3 is formed into the n-type semiconductor layer NS2 from the upper surface of the n-type semiconductor layer NS2, and is formed up to a predetermined depth from the upper surface of the n-type semiconductor layer NS2. A plane dimension (plane area) of the n-type semiconductor region NS3 is smaller than the plane dimension (plane area) of the n-type semiconductor layer NS2, and the n-type semiconductor region NS3 is included in the n-type semiconductor layer NS2 in plan view. An outer circumference side surface of the n-type semiconductor region NS3 is separated from the outer circumference side surface of the n-type semiconductor layer NS2 in plan view. The lower surface (bottom surface) of the n-type semiconductor region NS3 is shallower than the upper surface of the n-type semiconductor layer NS2 and, therefore, does not reach the n-type semiconductor layer NS1. That is, the n-type semiconductor region NS3 is formed in the n-type semiconductor layer NS2 such that the lower surface (bottom surface) of the n-type semiconductor region NS3 does not reach the n-type semiconductor layer NS1 in cross-sectional view. Therefore, the n-type semiconductor region NS3 does not contact with the n-type semiconductor layer NS1.

Note that when a depth of each component of the semiconductor chip CP is mentioned, a side near the back surface electrode BE is a deep side and a side far from the back surface electrode BE is a shallow side.

A portion, in which the n-type semiconductor region NS3 is not formed, in the n-type semiconductor layer NS2 is called an n-type semiconductor region (n-type semiconductor layer) NS2a. The lower surface (bottom surface) and the side surface of the n-type semiconductor region NS3 are covered with the n-type semiconductor region NS2a. That is, the lower surface and the side surface of the n-type semiconductor region NS3 contact with the n-type semiconductor region NS2a. The plane dimension (plane area) of the n-type semiconductor region NS3 is smaller than a plane dimension (plane area) of the n-type semiconductor region NS2a, and the n-type semiconductor region NS3 is included in the n-type semiconductor region NS2a in plan view.

Under the n-type semiconductor region NS3, the n-type semiconductor region NS2a exists. That is, between the n-type semiconductor region NS3 and the n-type semiconductor layer NS1, the n-type semiconductor region NS2a exists. The lower surface of the n-type semiconductor region NS2a contacts with the upper surface of the n-type semiconductor layer NS1. The outer circumference side surface of the n-type semiconductor layer NS2 is configured by an outer circumference side surface of the n-type semiconductor region NS2a. The upper surface of the n-type semiconductor layer NS2 is configured by the upper surface of the n-type semiconductor region NS2a and the upper surface of the n-type semiconductor region NS3. In plan view, the upper surface of the n-type semiconductor region NS3 is surrounded by the upper surface of the n-type semiconductor region NS2a.

An n-type impurity concentration of the n-type semiconductor layer NS1 is higher than an n-type impurity concentration of the n-type semiconductor layer NS2, and an n-type impurity concentration of the n-type semiconductor region NS3 is higher than the n-type impurity concentration of the n-type semiconductor layer NS2. That is, the n-type impurity concentration of the n-type semiconductor layer NS1 is higher than the n-type impurity concentration of the n-type semiconductor region NS2a, and the n-type impurity concentration of the n-type semiconductor region NS3 is higher than the n-type impurity concentration of the n-type semiconductor region NS2a.

The trench TR1 is formed into the n-type semiconductor layer NS2 (into the n-type semiconductor region NS3) from the upper surface of the n-type semiconductor layer NS2. The trench TR1 is formed up to a predetermined depth from the upper surface of the n-type semiconductor layer NS2. The trench TR1 does not penetrate through the n-type semiconductor layer NS2, and a bottom surface (lower surface) of the trench TR1 is shallower than the lower surface of the n-type semiconductor layer NS2 and, therefore, does not reach the n-type semiconductor layer NS1. Although not shown in the figure, the trench TR1 is formed into, for example, a lattice shape, a stripe shape, or an island-like shape in plan view. The trench TR1 is included in the n-type semiconductor region NS3 in plan view.

In a case of FIG. 3, the trench TR1 is formed in the n-type semiconductor region NS3, and a depth of the bottom surface of the trench TR1 is shallower than a depth of the lower surface (bottom surface) of the n-type semiconductor region NS3. Therefore, the bottom surface and a side surface of the trench TR1 are covered with the n-type semiconductor region NS3, and the n-type semiconductor region NS3 exists under the bottom surface of the trench TR1.

On the n-type semiconductor region NS3, the polysilicon electrode PE is formed via the insulating film (capacitive insulating film) CZ. A part of the polysilicon electrode PE is embedded in the trench TR1 via the insulating film CZ.

The insulating film CZ is formed on each of the upper surface of the n-type semiconductor layer NS2, the bottom surface and the side surface of the trench TR1. That is, the insulating film CZ is formed on an inner surface (bottom surface and side surface) of the trench TR1 and on the upper surface of the n-type semiconductor region NS3 located outside the trench TR1. The insulating film CZ contacts with the n-type semiconductor region NS3 (n-type semiconductor layer NS2), and contacts with the polysilicon electrode PE. The insulating film CZ is made of, for example, a silicon oxide film.

The polysilicon electrode PE is formed on the insulating film CZ so as to embed the inside of the trench TR1. The polysilicon electrode PE is made of a conductive film and, here, is made of a doped polysilicon film. Since the insulating film CZ is interposed between the polysilicon electrode PE and the n-type semiconductor region NS3 (n-type semiconductor layer NS2), the polysilicon electrode PE does not contact with the n-type semiconductor region NS3 (n-type semiconductor layer NS2).

The polysilicon electrode PE integrally has a portion located in the trench TR1 (that is, a portion embedded in the trench TR1 via the insulating film CZ), and a portion located on the upper surface of the n-type semiconductor region NS3 located outside the trench TR1. In plan view, the trench TR1 is included in the n-type semiconductor region NS3. Accordingly, in plan view, the polysilicon electrode PE is included in the n-type semiconductor region NS3.

An insulating film PA is formed on the upper surface of the n-type semiconductor layer NS2. The insulating film PA is made of, for example, a silicon oxide film. The insulating film PA has an opening OP1. A part of the polysilicon electrode PE is exposed from the opening OP1 of the insulating film PA. A portion, which is not covered with the insulating film CZ, in the upper surface of the n-type semiconductor layer NS2 is covered with the insulating film PA. In plan view, the opening OP1 is included in the polysilicon electrode PE. A portion (outer circumference portion) of the polysilicon electrode PE is covered with the insulating film PA.

The front surface electrode HE is formed on the polysilicon electrode PE exposed from the opening OP1 of the insulating film PA.

The front surface electrode HE is made of a metal film. Specifically, the front surface electrode HE is made of a single-layer metal film or a lamination film of a plurality of metal films. In plan view, the opening OP1 is included in the front surface electrode HE. The front surface electrode HE contacts with the polysilicon electrode PE, and is electrically connected to the polysilicon electrode PE. The outer circumference portion of the front surface electrode HE is located on the insulating film PA.

The back surface of the semiconductor chip CP is configured by a surface of the back surface electrode BE, and a surface of the semiconductor chip CP is configured by a surface (upper surface) of the front surface electrode HE and a surface (upper surface) of the insulating film PA. Note that the surface of the back surface electrode BE is a surface opposite a side that contacts with the n-type semiconductor layer NS1. The side surface of the semiconductor chip CP is configured by the side surface of the back surface electrode BE, the side surface of the n-type semiconductor layer NS1, the side surface of the n-type semiconductor layer NS2, and the side surface of the insulating film PA.

By the polysilicon electrode PE, the n-type semiconductor region NS3 (n-type semiconductor layer NS2), and the insulating film CZ, the capacitor (capacitive element) 2a (see FIG. 1 and FIG. 2) is formed. The insulating film CZ functions as a capacitive insulating film (dielectric film) of the capacitor 2a, the polysilicon electrode PE functions as one electrode (capacitor electrode) of the capacitor 2a, and the n-type semiconductor region NS3 (n-type semiconductor layer NS2) functions as the other electrode (capacitor electrode) of the capacitor 2a. By embedding the polysilicon electrode PE in the trench TR1 via the insulating film CZ, an effective electrode area of the capacitor 2a can be increased, so that a capacitive value of the capacitor 2a can be efficiently increased.

The front surface electrode HE is electrically connected to the polysilicon electrode PE. The back surface electrode BE is electrically connected to the n-type semiconductor layer NS1. Therefore, the back surface electrode BE is electrically connected to the n-type semiconductor region NS2a via the n-type semiconductor layer NS1 and is further electrically connected to the n-type semiconductor region NS3 via the n-type semiconductor region NS2a.

Therefore, a series circuit of the capacitor 2a and the resistance 2b is formed between the front surface electrode HE and the back surface electrode BE. The resistance 2b (see FIG. 1 and FIG. 2) is formed by the n-type semiconductor region NS3, the n-type semiconductor region NS2a, and the n-type semiconductor layer NS1. A resistance value of the resistance 2b is mainly determined by the n-type semiconductor region NS2a. This is because the n-type impurity concentration of the n-type semiconductor region NS2a is lower than the n-type impurity concentration of the n-type semiconductor region NS3 and is lower than the n-type impurity concentration of the n-type semiconductor layer NS1, so that a resistivity of the n-type semiconductor region NS2a is higher than a resistivity of the n-type semiconductor region NS3 and is higher than the a resistivity of the n-type semiconductor layer NS1.

To realize the above circuit of FIG. 1, the front surface electrode HE of the semiconductor chip CP may be electrically connected to the source S1 of the power MOSFET 1, and the back surface electrode BE of the semiconductor chip CP may be electrically connected to the drain D1 of the power MOSFET 1. To realize the above circuit of FIG. 2, the front surface electrode HE of the semiconductor chip CP may be electrically connected to the drain D1 of the power MOSFET 1, and the back surface electrode BE of the semiconductor chip CP may be electrically connected to the source S1 of the power MOSFET 1.

### <Manufacturing Process of Semiconductor Chip CP>

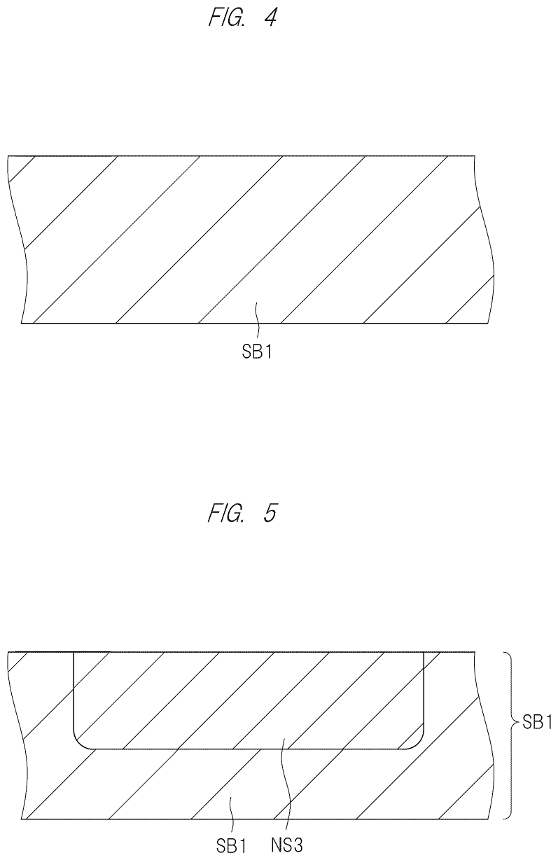

A manufacturing step of the semiconductor chip CP of the present embodiment will be explained with reference to FIG. 4 to FIG. 11. FIG. 4 to FIG. 11 are cross-sectional views during a manufacturing step of the semiconductor chip CP of the present embodiment.

As shown in FIG. 4, the n-type semiconductor substrate (semiconductor wafer) SB1 made of, for example, n-type monocrystal silicon the and like is prepared. The semiconductor substrate SB1 has a main surface and a back surface opposite the main surface.

Next, as shown in FIG. 5, the n-type semiconductor region NS3 is formed in the semiconductor substrate SB1 by using an ion implantation method. The n-type semiconductor region NS3 is formed up to the predetermined depth from the main surface of the semiconductor substrate SB1.

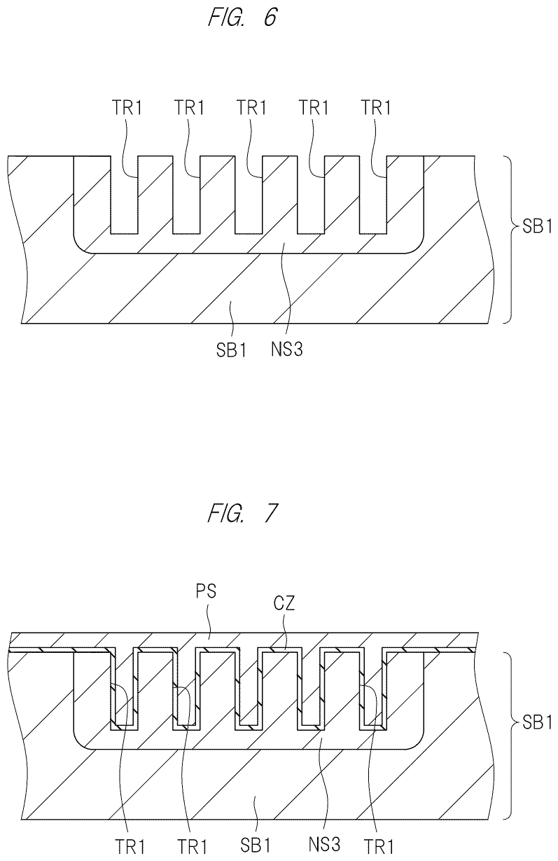

Next, as shown in FIG. 6, the trench TR1 is formed in the main surface of the semiconductor substrate SB1. The trench TR1 can be formed by using a photolithography technique and an etching technique.

The trench TR is formed into the n-type semiconductor region NS3 from the main surface of the semiconductor substrate SB1. The bottom surface of the trench is shallower than the bottom surface of the n-type semiconductor region NS3, and the part of the n-type semiconductor region NS3 exists under the bottom surface of the trench TR. The trench TR is included in the n-type semiconductor region NS3 in plan view.

Next, as shown in FIG. 7, by using, for example, a thermal oxidation method and the like, the insulating film CZ is formed on each of the main surface of the semiconductor substrate SB1 and the inner surface (bottom surface and side surface) of the trench TR. The insulating film CZ is made of a thin silicon oxide film and the like, and is formed on the bottom surface and the side surface of the trench TR1 and on the main surface of the semiconductor substrate SB1 located outside the trench TR1.

Next, as shown in FIG. 7, the polysilicon film PS is formed on the main surface of the semiconductor substrate SB1, that is, on the insulating film CZ by using a CVD method and the like so as to embed an inside of the trench TR1.

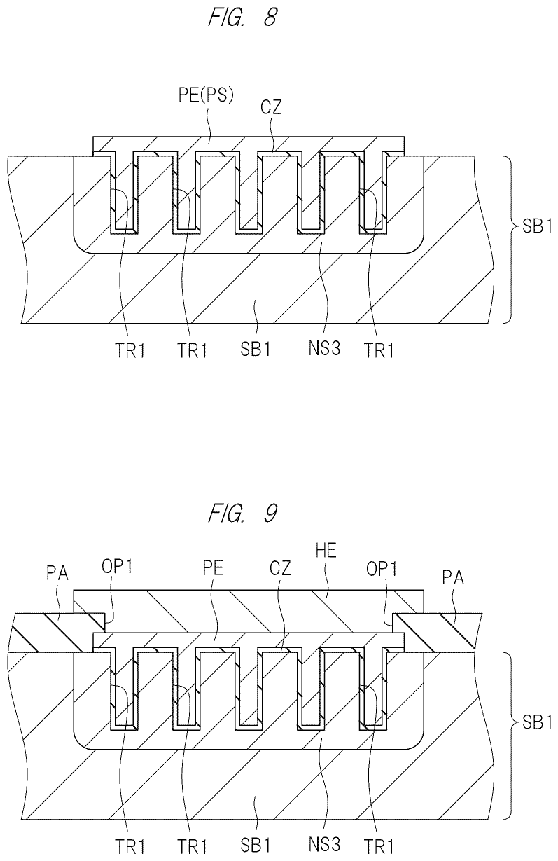

Next, after forming a photoresist pattern (not shown) on the polysilicon film PS, the polysilicon film PS is patterned by using the photoresist pattern as an etching mask to etch the polysilicon film PS. Consequently, as shown in FIG. 8, the polysilicon electrode PE made of the patterned polysilicon film PS is formed. The polysilicon electrode PE is formed on the insulating film CZ so as to the embed the inside of the trench TR.

Next, as shown in FIG. 9, after forming the insulating film PA on the main surface of the semiconductor substrate SB1 so as to cover the polysilicon electrode PE, the opening OP1 of the insulating film PA is formed by using, as the etching mask, the photoresist pattern (not shown) formed on the insulating film PA to etch the insulating film PA.

Next, as shown in FIG. 9, the front surface electrode HE is formed on the polysilicon electrode PE exposed from the opening OP1 of the insulating film PA.

For example, after forming an aluminum film on the polysilicon electrode PE exposed from the opening OP1 of the insulating film PA and on the insulating film PA, the photoresist pattern is formed on this aluminum film. Then, an electrolytic platting film is formed on the aluminum film exposed from the opening of the photoresist pattern. Then, the photoresist pattern is removed. Consequently, the front surface electrode HE made of a lamination film of the aluminum film and the electrolytic plating film can be formed.

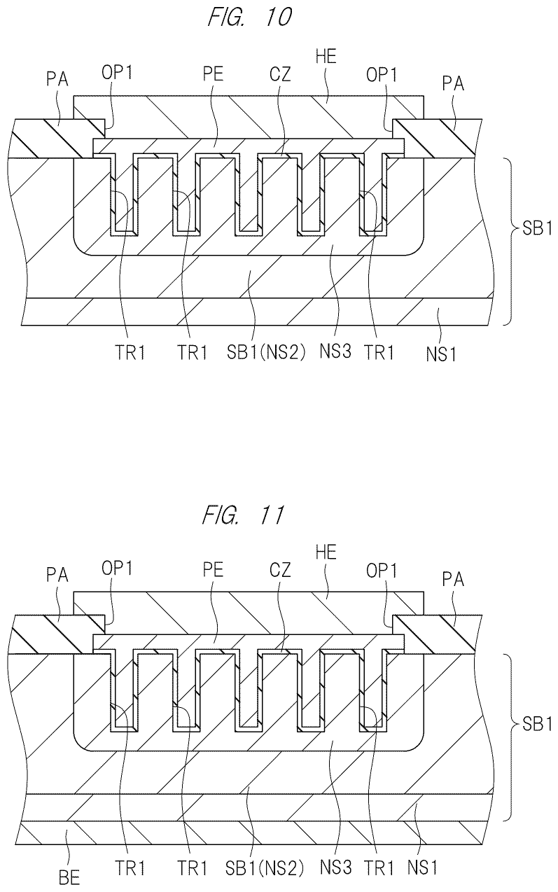

Next, as shown in FIG. 10, by ion-implanting the n-type impurities into the semiconductor substrate SB1 from the back surface of the semiconductor substrate SB1, the n-type semiconductor layer NS1 is formed in the semiconductor substrate SB1. The n-type semiconductor layer NS1 is formed up to the determined depth from the back surface of the semiconductor substrate SB1. The lower surface of the n-type semiconductor layer NS1 corresponds to the back surface of the semiconductor substrate SB1. A portion, which is located on the n-type semiconductor layer NS1, in the semiconductor substrate SB1 corresponds to the n-type semiconductor layer NS2. The upper surface of the n-type semiconductor layer NS2 corresponds to the main surface of the semiconductor substrate SB1. The bottom surface of the n-type semiconductor region NS3 does not reach the n-type semiconductor layer NS1.

Next, as shown in FIG. 11, the back surface electrode BE is formed on the back surface of the semiconductor substrate SB1. The back surface electrode BE can be formed by using, for example, a spattering method.

Then, the semiconductor substrate SB1 is cut by dicing. At this time, the back surface electrode BE and the insulating film PA are also cut together with the semiconductor substrate SB1.

In this way, the above semiconductor chip CP shown by FIG. 3 can be manufactured.

### <Modified Example of Manufacturing Process of Semiconductor Chip CP>

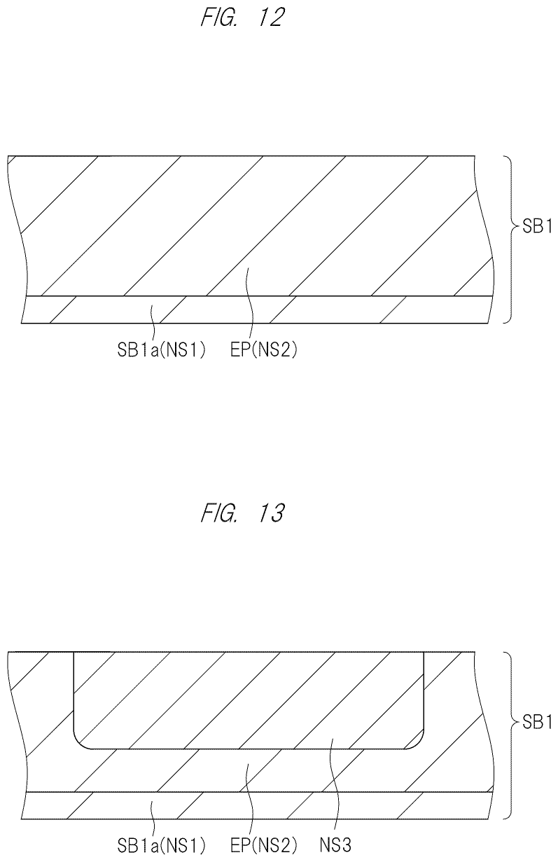

A modified example of the manufacturing step of the semiconductor chip CP of the present embodiment will be explained with reference to FIG. 12 to FIG. 17. FIG. 12 to FIG. 17 are cross-sectional views during the manufacturing step of the semiconductor chip CP of the present embodiment.

As shown in FIG. 12, the semiconductor substrate (semiconductor wafer) SB1 is prepared. In a case of the modified example, the semiconductor substrate SB1 is a so-called epitaxial wafer. Therefore, as shown in FIG. 12, the semiconductor substrate SB1 has an n-type substrate body SB1a made of an n-type monocrystalline silicon substrate, and an n-type semiconductor layer EP made of n-type monocrystalline silicon formed on the n-type substrate body SB1a by epitaxial growth. The n-type semiconductor layer EP and the n-type substrate body SB1a contact with each other. An n-type impurity concentration of the n-type semiconductor layer EP is lower than an n-type impurity concentration of the n-type substrate body SB1a.

The main surface of the semiconductor substrate SB1 has the same meaning as a main surface of the n-type semiconductor layer EP. In addition, the back surface of the semiconductor substrate SB1 has the same meaning as a back surface of the n-type semiconductor substrate SB. The main surface of the semiconductor substrate SB1 and back surface of the semiconductor substrate SB1 are located opposite each other.

The n-type substrate body SB1a corresponds to the n-type semiconductor layer NS1. The n-type semiconductor layer EP corresponds to the n-type semiconductor layer NS2.

Subsequent steps are almost the same as the above steps of FIG. 5 to FIG. 11 except for not performing an ion implantation step for forming the n-type semiconductor layer NS1.

That is, as shown in FIG. 13, the n-type semiconductor region NS3 is formed in the n-type semiconductor layer EP of the semiconductor substrate SB1 by using the ion implantation method. The bottom surface of the n-type semiconductor region NS3 does not reach the n-type substrate body SB1a.

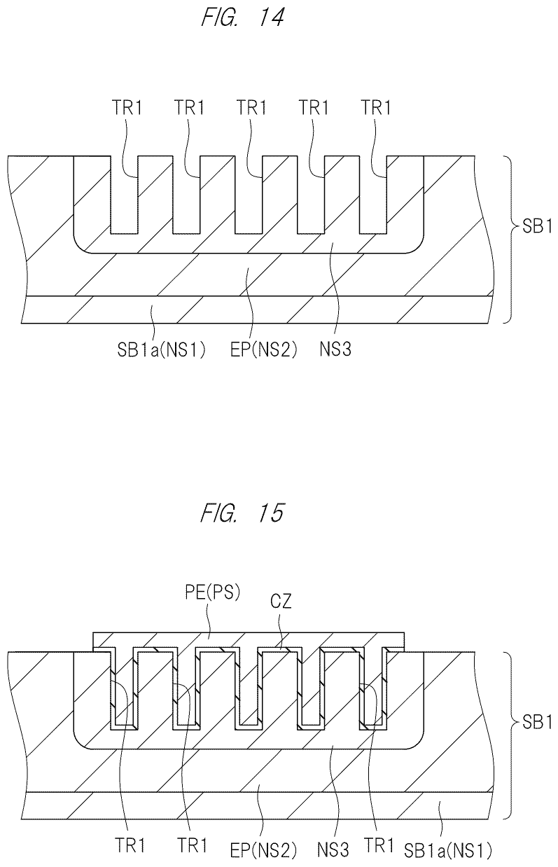

Next, as shown in FIG. 14, the trench TR1 is formed in the main surface of the semiconductor substrate SB1.

Next, as shown in FIG. 15, the insulating film CZ is formed on each of the main surface of the semiconductor substrate SB1 and the inner surface (bottom surface and the side surface) of the trench TR1.

Next, after forming the polysilicon film PS on the main surface of the semiconductor substrate SB1, that is, on the insulating film CZ so as to embed the inside of the trench TR1, the polysilicon electrode PE is formed by patterning the polysilicon film PS.

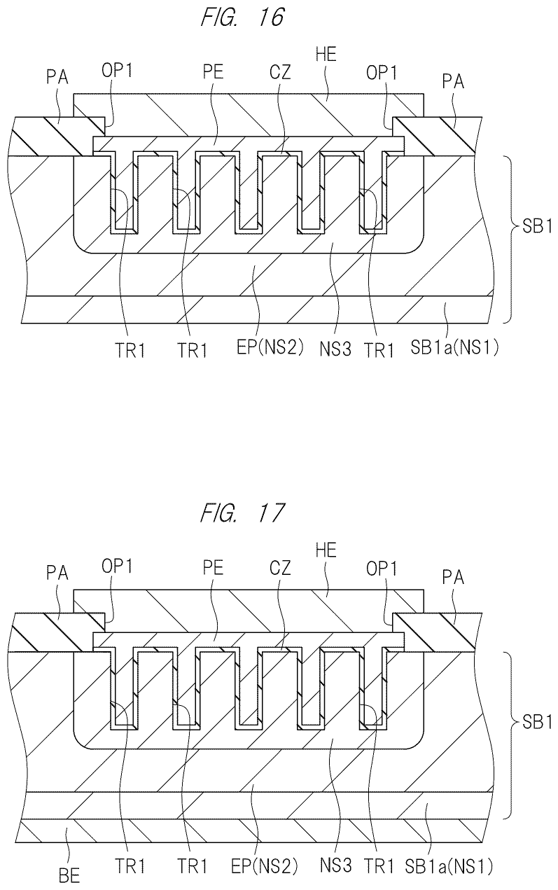

Next, as shown in FIG. 16, after forming the insulating film PA, the opening OP1 is formed in the insulating film PA.

Next, as shown in FIG. 16, the front surface electrode HE is formed on the polysilicon electrode PE exposed from the opening OP1 of the insulating film PA.

Next, as shown in FIG. 17, the back surface electrode is formed on the back surface of the semiconductor BE substrate SB1.

Then, the semiconductor substrate SB1, the back surface electrode BE, and the insulating film PA are cut by the dicing.

In this way, the above semiconductor chip CP of FIG. 3 can be manufactured.

### <Structure of Semiconductor Package PKG>

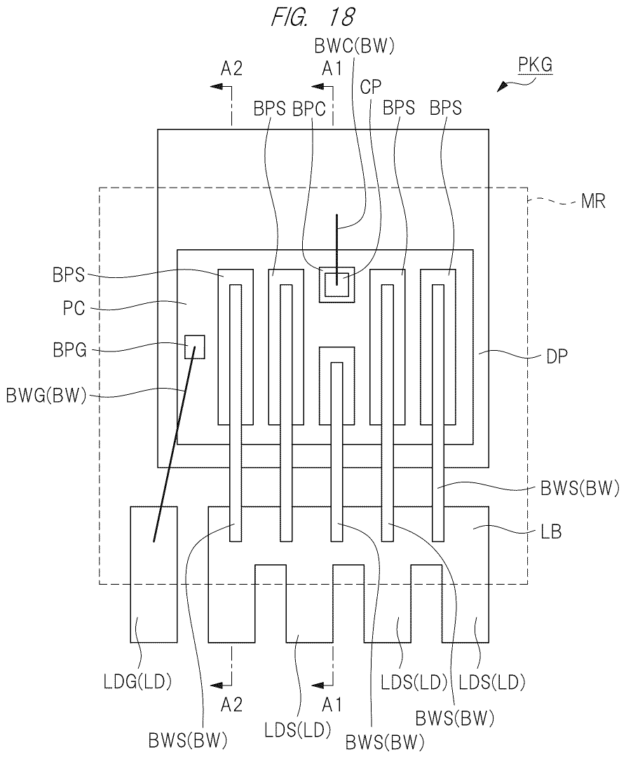

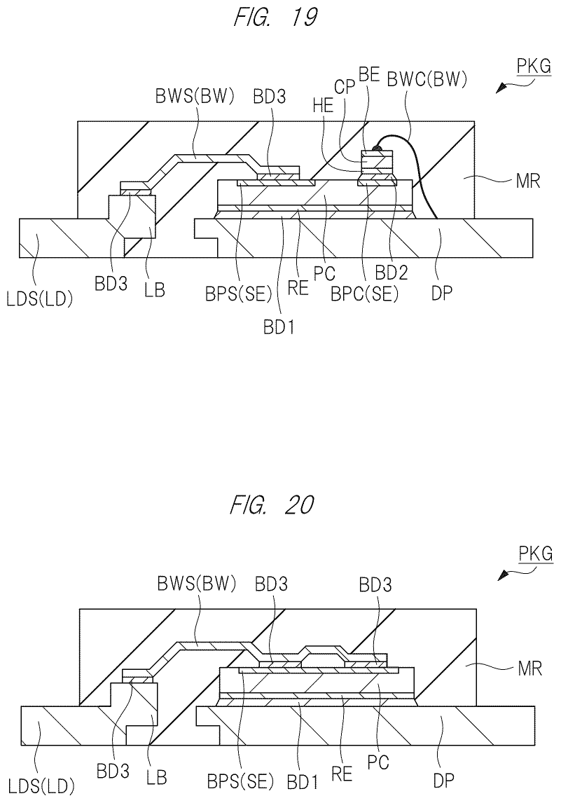

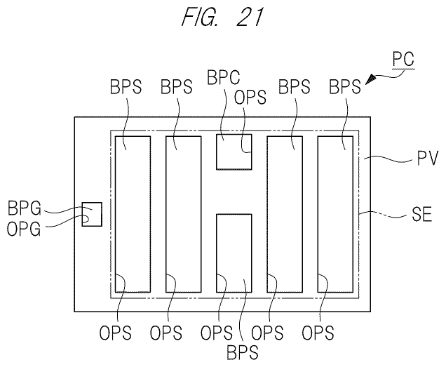

FIG. a 18 is plan perspective view showing semiconductor package (semiconductor device, electronic device) PKG using the semiconductor chip CP of the present embodiment. FIG. 18 sees through a sealing portion MR. FIG. 19 and FIG. 20 are cross-sectional views of the semiconductor package PKG. FIG. 19 corresponds to a cross-sectional view taken along line A-A line of FIG. 18, and FIG. 20 corresponds to a cross-sectional view taken along line A1-A1 line of FIG. 18. FIG. 21 is a plan view (top view) of the power semiconductor chip PC used in the semiconductor package PG. FIG. 21 shows an outer circumferential position of the source electrode SE by a dash-double-dot line. The semiconductor package PKG can be regarded as the semiconductor device or the electronic device.

As shown in FIG. 18, FIG. 19, FIG. 20, and FIG. 21, the semiconductor package PKG of the present embodiment has the semiconductor chip CP, the power semiconductor chip PC, a die pad DP, a plurality of conductive wires (bonding wires) BW, a plurality of leads LD, a lead coupling portion LB, and a sealing portion (sealing resin portion) MR for sealing them.

The sealing portion MR is made of, for example, a resin material such as a thermosetting rein material, and can also include a filler and the like.

The die pad DP, the lead coupling portion LB, the plurality of leads LD are made of a metal material such as copper (Cu) or a copper alloy.

The plurality of leads LD include a gate lead LDG and a plurality of source leads LDS. The plurality of source leads LDS are coupled to the common lead coupling portion LB. The plurality of source leads LDS and the lead coupling portion LB are integrally formed. The lead coupling portion LB is sealed in the sealing portion MR. A part of each lead LD is sealed in the sealing portion MR, and the other part of each lead LD is exposed from the sealing portion MR.

A part of the die pad DP is sealed in the sealing portion MR, and a lower surface of the die pad DP is exposed from a lower surface of the sealing portion MR. A part of the die pad DP may protrude from a side surface of the sealing portion MR.

The power semiconductor chip PC is mounted on an upper surface of the die pad DP via a bonding material (die bonding material) BD1 having conductivity. The die pad DP is a chip mounting portion for mounting the power semiconductor chip PC.

The power semiconductor chip PC is a semiconductor chip including the above power MOSFET 1. The power semiconductor chip PC has an upper surface and a back surface opposite the upper surface, and has a gate pad (gate bonding pad) BPG, a plurality of source pads (source bonding pads) BPS, and a pad (chip mounting bonding pad) BPC on an upper surface side, and has a back surface electrode RE (also called a “back surface drain electrode” that the first semiconductor chip has) on a back surface side. The gate pad BPG is electrically connected to the gate of the power MOSFET 1 formed in the power semiconductor chip PC. The plurality of source pads BPS and the pad BPC are electrically connected to the source of the power MOSFET 1 formed in the power semiconductor chip PC. The back surface electrode RE is electrically connected to the drain of the power MOSFET 1 formed in the power semiconductor chip PC.

The power semiconductor chip PC is disposed on the upper surface of the die pad DP via the bonding material BD1 having conductivity such that the back surface electrode RE of the power semiconductor chip PC opposes the upper surface of the die pad DP via the bonding material BD1. The bonding material BD1 is made of, for example, solder, silver (Ag) paste, sintered Ag (sintered silver), or the like. Therefore, the back surface electrode RE of the power semiconductor chip PC is electrically connected to the die pad DP via the bonding material BD1 having conductivity. The power semiconductor chip PC is sealed in the sealing portion MR, and is not exposed from the sealing portion MR.

Each of the plurality of wires BW is a conductive connection member. The plurality of wires BW include the gate wire BWG, the plurality of source wires BWS, and the wires BWC. The plurality of wires BW are sealed in the sealing portion MR, and is not exposed from the sealing portion MR.

The gate pad BPG of the power semiconductor chip PC and the gate lead LDG are electrically connected to each other via the gate wire BWG. The gate lead LDG functions as an external terminal electrically connected to the gate of the power MOSFET 1.

The plurality of source pads BPS of the power semiconductor chip PC and the lead coupling portion LB are electrically connected to one another via the plurality of source wires BWS. Therefore, the plurality of source leads LDS are electrically connected to the plurality of source pads BPS via the lead coupling portion LB and the plurality of source wires BWS. The plurality of source leads LDS functions as an external terminal electrically connected to the source of the power MOSFET 1. In a case of FIG. 20, each of plurality of source wires BWS is connected to the lead coupling portion LB via a bonding material BD3 having conductivity such as solder, and is connected to the source pad BPS via the bonding material BD3 having conductivity.

Each diameter of the plurality of source wires BWS is larger than a diameter of the gate wire BWG, and is larger than a diameter of the wire BWC. In other words, each diameter of the gate wire BWG and the wire BWC is smaller than a diameter of the source wire BWS. Consequently, a size of the gate pad BPG bonded by the gate wire BWG and a size of the gate pad BPG joined by the wire BWC can be relatively reduced, while a size of the source pad BPC joined by the source wire BWS can be relatively increased. Then, the plurality of source wires BWS each having such a large diameter can be joined to the source pad BPS, so that a width of a path (current path) between the plurality of source leads LDS and the plurality of source pads BPS of the power semiconductor chip PC can be increased. That is, since a resistance value between the drain and the source of the power semiconductor chip PC can be decreased, on-resistance of the power MOSFET 1 can be reduced. Accordingly, conduction loss in the semiconductor package PKG can be reduced.

The semiconductor chip CP is mounted on the pad BPC of the power semiconductor chip PC via a bonding material (die bonding material) BD2 having conductivity. The semiconductor chip CP is disposed on the pad BPC of the power semiconductor chip PC via the bonding material BD2 having conductivity such that the front surface electrode HE of the semiconductor chip CP opposes the pad BP of the power semiconductor chip PC via the bonding material BD2. The bonding material BD2 is made of, for example, solder, silver (Ag) paste, sintered Ag (sintered silver), or the like. Therefore, the front surface electrode HE of the semiconductor chip CP is electrically connected to the pad BP of the power semiconductor chip PC via the bonding material BD2 having conductivity. The semiconductor chip CP is sealed in the sealing portion MR, and is not exposed from the sealing portion MR.

The back surface electrode BE of the semiconductor chip CP and the die pad DP are electrically connected to each other via the wire BWC. Specifically, one end portion of the wire BWC is connected to the back surface electrode BE of the semiconductor chip CP, and the other end portion of the wire BWC is connected to the upper surface of the die pad DP. Therefore, the back surface electrode BE of the semiconductor chip CP is electrically connected to the die pad DP via the wire BWC, and is further electrically connected to the back surface electrode RE of the power semiconductor chip PC via the die pad DP and the bonding material BD1 having conductivity.

The lower surface of the die pad DP is exposed from the lower surface of the sealing portion MR. The die pad DP exposed from the lower surface of the sealing portion MR functions as an external terminal electrically connected to the drain of the power MOSFET 1. A conduction current (on-current) of the power MOSFET 1 formed in the power semiconductor chip PC flows between the die pad DP and the plurality of source leads LDS. Heat generated at a time of operating the power MOSFET 1 can be mainly dissipated outside the semiconductor package PKG via the bonding material BD1 and the die pad DP from the back surface of the power MOSFET 1.

### <Manufacturing Process of Semiconductor Package PKG>

A manufacturing step of the semiconductor package PKG will be explained.

A lead frame integrally having the die pad DP, the plurality of leads LD, and the lead coupling portion LB is prepared. In the lead frame, the die pad DP and the plurality of leads LD are integrally coupled to a framework (not shown) of the lead frame.

Next, by performing a die boding step, the power semiconductor chip PC is mounted on the upper surface of the die pad DP of the lead frame via the bonding material BD1 having conductivity. Consequently, the front surface electrode BE of the power semiconductor chip PC is joined to the die pad DP via the bonding material BD1 having conductivity.

Next, by performing the die bonding step, the semiconductor chip CP is mounted on the pad BP of the power semiconductor chip PC via the bonding material BD2 having conductivity. Consequently, the back surface electrode BE of the semiconductor chip CP is joined to the pad BPC of the power semiconductor chip PC via the bonding material BD2 having conductivity.

Next, a wire bonding step is performed. Specifically, the gate pad BPG of the power semiconductor chip PC and the gate lead LDG are electrically connected to each other via the gate wire BWG, the plurality of source pads BPS of the power semiconductor chip PC and the lead coupling portion LB are respectively electrically connected to one another via the plurality of source wires BWS, and the back surface electrode BE of the semiconductor chip CP and the die pad DP are electrically connected to each other via the wire BWC.

Next, by performing a molding step, the sealing portion MR is formed. Then, the die pad DP and the lead LD are cut from the lead frame. Consequently, the semiconductor package PKG can be manufactured.

### <Structure of Power Semiconductor Chip PC>

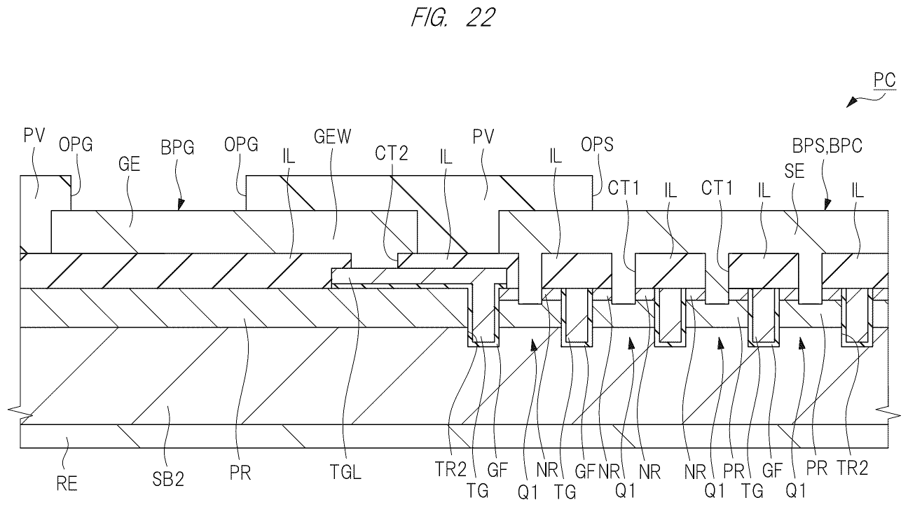

FIG. 22 is a cross-sectional view showing a main part of the power semiconductor chip PC.

The semiconductor chip PC is a semiconductor chip including the power MOSFET 1, and the power MOSFET 1 is formed on a semiconductor substrate SB2 configurating the semiconductor chip PC.

As shown in FIG. 22, the power semiconductor chip PC has the semiconductor substrate SB2, an interlayer insulating film IL, the back surface electrode RE, the source electrode SE, the gate electrode GE, a gate wiring GEW, an insulating film PV, a trench gate electrode TG, a gate insulating film GF, a gate drawing wiring portion TGL, and an n-type semiconductor region NR and a p-type semiconductor region PR that are formed in the semiconductor substrate SB.

The semiconductor substrate SB2 is an n-type semiconductor substrate made of, for example, an n-type monocrystalline silicon substrate and the like. A semiconductor substrate (so-called epitaxial wafer) having a substrate body made of an n-type monocrystalline silicon substrate, and an epitaxial layer made of n-type monocrystalline silicon formed on the substrate body can be also used as the semiconductor substrate SB2.

The semiconductor substrate SB2 has a main surface, and a back surface located opposite the main surface. The interlayer insulating film IL is formed on the main surface of the semiconductor substrate SB2, and the back surface electrode RE is formed on the back surface of the semiconductor substrate SB.

On the semiconductor substrate SB2, a trench gate type MOSFET is formed. The trench gate type MOSFET has a trench type gate structure. The trench type gate structure corresponds to a gate electrode structure embedded in the trench formed in the substrate.

A specific configuration of the trench gate type MOSFET formed on the semiconductor substrate SB2 will be explained below.

The trench gate type MOSFET configurating the power MOSFET 1 is formed on the main surface of the semiconductor substrate SB2. Specifically, a plurality of unit transistor cells Q1 formed on the main surface of the semiconductor substrate SB2, and by the plurality of unit transistor cells Q1 formed on the semiconductor substrate SB2 being connected in parallel, the power MOSFET 1 is formed. Each unit transistor cell Q1 is configured by the trench gate type MOSFET. Here, on the main surface of the semiconductor substrate SB2, a planar region in which the plurality of unit transistor cells Q1 configurating the power MOSFET 1 are formed is called a transistor cell region.

The semiconductor substrate SB2 has a function as a drain region of the above unit transistor cell Q1. On the back surface of the semiconductor substrate SB2, the back surface electrode RE for the drain is formed. The back surface electrode RE is formed on the entire back surface of the semiconductor substrate SB2. The back surface electrode RE is made of, for example, a lamination film of a titanium (Ti) film contacting with the semiconductor substrate SB2, a nickel (Ni) film on the titanium film, a gold (Au) film on the nickel film. The back surface electrode RE is electrically connected to the drain region of the plurality of unit transistor cells Q1. Therefore, the back surface electrode BE can function as the drain electrode electrically connected to the drain of the power MOSFET 1.

The p-type semiconductor region PR is formed in the semiconductor substrate SB2 in the transistor cell region. The p-type semiconductor region PR can function as the channel forming region of the above unit transistor cells Q1.

In the semiconductor substrate SB2, the n-type semiconductor region (source region) NR is formed on the p-type semiconductor region PR. The n-type semiconductor region NR can function as the source region of the above unit transistor cells Q1. The p-type semiconductor region PR exists under the n-type semiconductor region NR. The semiconductor substrate SB2 interposed between the p-type semiconductor region PR and the back surface electrode RE maintains an n-type conductivity type, and can function as the drain region of the above unit transistor cells Q1.

In the semiconductor substrate SB2, a super junction structure (not shown) can be also formed under the p-type semiconductor region PR.

A trench TR2 is formed in the main surface of the semiconductor substrate SB2, and the trench gate TG is embedded in the trench TR2 via the gate insulating film GF. The trench gate electrode TG is made of, for example, a doped polysilicon film. The gate insulating film GF is made of, for example, a silicon oxide film, and is formed on an inner surface (bottom surface and side surface) of the trench TR2. Although not shown in the figure, the trench TR2 is formed into, for example, a lattice shape or a stripe shape in plan view.

Note that a case in which the plan view is mentioned about the components of the power semiconductor chip CP corresponds to a case of being viewed from a plane nearly parallel to the main surface or the back surface of the semiconductor substrate SB2 configurating the power semiconductor chip PC.

The trench TR2 is formed from the main surface of the semiconductor substrate SB2 so as to penetrate through the n-type semiconductor region NR and the p-type semiconductor region PR. The bottom surface of the trench TR2 is deeper than the bottom surface of the n-type semiconductor region NR, and is deeper than the bottom surface of the p-type semiconductor region PR. The n-type semiconductor region NR is adjacent to the trench gate electrode TG via the gate insulating film GF. The p-type semiconductor region PR is adjacent to the trench gate electrode TG via the gate insulating film GF.

Next, an upper layer structure of the semiconductor substrate SB2 will be explained.

The interlayer insulating film IL is formed on the main surface of the semiconductor substrate SB2 so as to cover the trench gate electrode TG. The interlayer insulating film IL is made of, for example, a silicon oxide film.

The respective trench gate electrodes TG of the plurality of unit transistor cells Q1 are integrally coupled to one another in a region not shown by the cross-sectional view of FIG. 22. The gate drawing wiring portion TGL formed integrally with the trench gate electrode TG is formed on the main surface of the semiconductor substrate SB2 via the gate insulating film GF outside the trench TR2.

A source contact hole CT1 and a gate contact hole CT2 are formed in the interlayer insulating film IL. The contact hole CT1 is disposed between the adjacent trenches TR2 in plan view. The contact hole CT2 is disposed on the gate drawing wiring portion TGL.

The source electrode SE, the gate electrode GE, and the gate wiring GEW are formed on the interlayer insulating film IL. The gate electrode GE is formed integrally with the gate wiring GEW. The source electrode SE is separated from the gate electrode GE and is separated from the gate wiring GEW. In plan view, the source electrode SE is formed so as to cover the entire transistor cell region.

Each of the source electrode SE, the gate electrode GE, and the gate wiring GEW is made of, for example, a metal film such as an aluminum alloy film. A part of the source electrode SE is embedded in the source contact hole CT1. A portion, which is embedded in the source contact hole CT1, in the source electrode SE is called a source via portion. A part of the gate wiring GEW is embedded in the gate contact hole CT2. A portion, which is embedded in the gate contact hole CT2, in the gate wiring GEW is called a gate via portion.

The source contact hole CT1 penetrates through the interlayer insulating film IL and the n-type semiconductor region NR, and reaches the p-type semiconductor region PR. Therefore, the source via portion embedded in the source contact hole CT1 penetrates through the interlayer insulating film IL and the n-type semiconductor region NR, and reaches the p-type semiconductor region PR. The source via portion contacts with both of the n-type semiconductor region NR and the p-type semiconductor region PR, and so is electrically connected to both of the n-type semiconductor region NR and the p-type semiconductor region PR.

The source region (n-type semiconductor region NR) and the channel forming region (p-type semiconductor region PR) of the plurality of unit transistor cells Q1 disposed in the transistor cell region are electrically connected to the common source electrode SE via the plurality of source via portions. In this case, the source electrode SE is used also as a source wiring for electrically connecting the source regions (n-type semiconductor regions NR) of the plurality of unit transistor cells Q1 to one another. Therefore, the source electrode SE can function as a source electrode electrically connected the source of the power NOSFET 1.

The gate wiring GEW is electrically connected to the gate drawing wiring portion TGL via the gate via portion. Therefore, the trench gate electrode TG of the plurality of unit transistor cells Q1 is electrically connected to the gate electrode GE via the gate drawing wiring portion TGL and the gate wiring GEW. Accordingly, the gate electrode GE can function as a gate electrode electrically connected to the gate of the power MOSFET 1.

The insulating film PV as a passivation film is formed on the interlayer insulating film IL so as to cover a part of the source electrode SE, a part of the gate electrode GE and the gate wiring GE. The insulating film PV is made of, for example, a resin film such as a polyimide resin.

A plurality of source opening OPS and a gate opening OPG are formed in the insulating film PV. The part of the gate electrode GE is exposed from the gate opening OPG of the insulating film PV. By the gate electrode GE exposed from the gate opening OPG of the insulating film PV, a gate pad BPG is formed. The gate pad BPG (gate electrode GE) is electrically connected to the trench gate electrode TG of the plurality of unit transistor cells Q1 via the gate wiring GEW and the gate drawing wiring portion TGL.

The part of the source electrode SE is exposed from the plurality of source openings OPS of the insulating film PV. That is, the plurality of source openings OPS are disposed on the common source electrode SE, and the common source electrode SE is exposed from each of the plurality of source openings OPS. Each of the above pad BPS and the above plurality of source pads BPS is configured by the source electrode SE exposed from the source opening OPS of the insulating film PV. That is, the pad BPC and the plurality of source pads BPS are formed by the common source electrode SE, and so are electrically connected to one another. The pad BPC and the plurality of source pads BPS are electrically connected to the source electrode (n-type semiconductor region NR) of the plurality of unit transistor cells Q1 via the source electrode SE.

A plating film (not shown) may be formed on the source electrode SE exposed from the plurality of source openings OPS of the insulating film PV and on the gate electrode GE exposed from the gate opening OPG of the insulating film PV. The plating film is made of, for example, a nickel plating film, and a gold plating film on the nickel plating film. At this case, each of the pad BPC and the plurality of source pads BPS is configured by the source electrode SE and the plating film on the source electrode SE, and the gate pad BPG is configurated by the gate electrode GE and the plating film on the gate electrode GE.

In the power semiconductor chip PC having such a configuration, an operating current of the power MOSFET 1 flows between the source electrode SE and the back surface electrode RE for the drain. That is, the operating current of the trench gate type MOSFET formed in the transistor cell region flows in a thickness direction of the semiconductor substrate SB2. Therefore, the trench gate type MOSFET formed in the transistor cell region is a vertical transistor. Here, the vertical transistor corresponds to a transistor in which the operating current flows in the thickness direction of the semiconductor substrate SB2.

The above body diode 3 (see FIG. 1 and FIG. 2) corresponds to a parasitic PN diode configurated by the p-type semiconductor region PR and the n-type semiconductor substrate SB2.

<Mounting of Semiconductor Chip CP onto Power Semiconductor Chip PC>

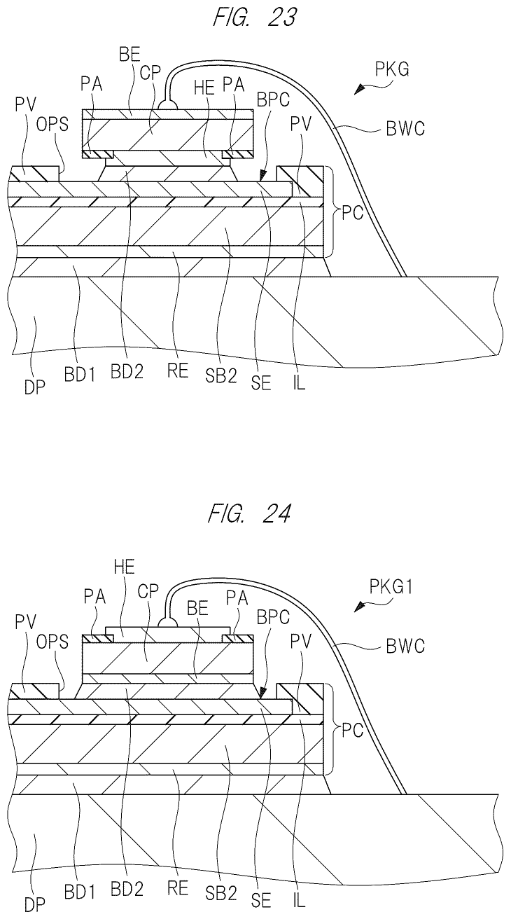

FIG. 23 is a partially enlarged cross-sectional view enlarging and showing a part of FIG. 19. Note that in FIG. 23, the illumination of the sealing portion MR is omitted.

As shown in FIG. 19 and FIG. 23, the semiconductor chip CP is mounted on the pad BPC (source electrode SE) of the power semiconductor chip PC via the bonding material BD2 having conductivity. The semiconductor chip CP is disposed on the pad BPC of the power semiconductor chip PC via the bonding material BD2 having conductivity such that the front surface electrode HE of the semiconductor chip CP opposes the pad BPC (source electrode SE) of the power semiconductor chip PC via the bonding material BD2. Therefore, the front surface electrode HE of the semiconductor chip CP is joined to the source electrode SE of the power semiconductor chip PC via the bonding material BD2 having conductivity, and is electrically to it. The back surface electrode BE of the semiconductor chip CP is electrically connected to the die pad DP via the wire BWC, and is further electrically connected to the back surface electrode RE of the power semiconductor chip PC via the die pad DP and the bonding material BD1 having conductivity.

Therefore, the front surface electrode HE of the semiconductor chip CP is electrically connected to the source of the power MOSFET 1 formed in the power semiconductor chip PC via the bonding material BD2 having conductivity and the pad BPC (source electrode SE) of the power semiconductor chip PC. Then, the back surface electrode BE of the semiconductor chip CP is electrically connected to the drain of the power MOSFET 1 formed in the power semiconductor chip PC via the wire BWC, the die pad DP, the bonding material BD1 having conductivity, and the back surface electrode RE. Consequently, as shown in FIG. 1, the power MOSFET 1 formed in the power semiconductor chip PC and the snubber circuit 2 formed in the semiconductor chip CP are connected in parallel.

In addition, when the semiconductor chip CP is mounted on the pad BPC (source electrode SE) of the power semiconductor chip PC via the bonding material BD2, the side surface of the opening OPS of the insulating film PA can prevent the bonding material BD2 from excessively spreading.

FIG. 24 is a partially enlarged cross-sectional view enlarging and showing a part of a semiconductor package PKG of a modified example, and corresponds to FIG. 23. In FIG. 24, the illumination of the sealing portion MR is omitted. The semiconductor package PKG of the modified example shown by FIG. 24 is called a semiconductor package PKG1.

The semiconductor package PKG1 of the modified example shown by FIG. 24 is different from the semiconductor package PKG shown by FIG. 23 in a direction in which the semiconductor chip CP is mounted. A different point between the semiconductor package PKG1 of the modified example shown by FIG. 24 and the semiconductor package PKG shown by FIG. 23 will be explained later.

As shown in FIG. 24, in the semiconductor package PKG1 of the modified example, the semiconductor chip CP is disposed on the pad BP of the power semiconductor chip PC via the bonding material BD2 having conductivity such that the back surface electrode BE of the semiconductor chip CP opposes the pad BPC (source electrode SE) of the power semiconductor chip C via the bonding material BD2. Therefore, the back surface electrode BE of the semiconductor chip CP is jointed to the source electrode SE of the power semiconductor chip PC via the bonding material BD2 having conductivity, and is electrically connected to it. The front surface electrode HE of the semiconductor chip CP is electrically connected to the die pad DP via the wire BWC. Specifically, one end portion of the wire BWC is connected to the back surface electrode BE of the semiconductor chip CP, and the other end portion of the wire BWC is connected to the upper surface of the die pad DP. Therefore, the back surface electrode BE of the semiconductor chip CP is electrically connected to the back surface electrode RE of the power semiconductor chip PC via the wire BWC, the die pad DP, and the bonding material BD1 having conductivity.

Therefore, in a case of the semiconductor package PKG1 of the modified example shown by FIG. 24, the front surface electrode HE of the semiconductor chip CP is electrically connected to the drain of the power MOSFET 1 formed in the power semiconductor chip PC via the wire BWC, the die pad DP, the bonding material BD1 having conductivity, and the back surface electrode RE. Then, the back surface electrode BE of the semiconductor chip CP is electrically connected to the source of the power MOSFET 1 formed in the power semiconductor chip PC via the bonding material BD2 having conductivity and the pad BPC (source electrode SE) of the power semiconductor chip PC. Consequently, as shown in FIG. 2, the power MOSFET 1 formed in the power semiconductor chip PC and the snubber circuit 2 formed in the semiconductor chip CP are connected in parallel. That is, the above circuit configuration of FIG. 1 corresponds to the semiconductor package PKG shown by FIG. 23, and the above circuit configuration of FIG. 2 corresponds to the semiconductor package PKG1 shown by FIG. 24.

### <Main Features and Effects>

In the present embodiment, the snubber circuit 2 is formed not in power semiconductor chip PC including the power MOSFET 1 but by the semiconductor chip CP separated from the power semiconductor chip PC. Since the configuration necessary for the snubber circuit 2 does not require being formed in the power semiconductor chip PC, the structure of the power semiconductor chip PC can be optimized to a structure suitable for the power MOSFET 1. In addition, the structure of the semiconductor chip CP can be optimized to a structure suitable for the snubber circuit 2.

The semiconductor chip CP of the present embodiment has the front surface electrode HE and the back surface electrode BE, and the snubber circuit 2 (series circuit of the capacitor 2a and the resistance 2b) is formed between the front surface electrode HE and the back surface electrode BE.

A case that is different from the present embodiment and in which electrodes of both ends of the snubber circuit 2 are both disposed on a surface side of the semiconductor chip CP is assumed. At this case, the plane dimension (plane area) of the semiconductor chip including the snubber circuit 2 becomes large, the manufacturing costs of the semiconductor chip CP including the snubber circuit 2 may be increased. In addition, the capacitive value of the capacitor 2a and the resistance value of the resistance 2b are difficult to control independently.

In contrast, in the present embodiment, the electrodes (here, front surface electrode HE and back surface electrode BE) of the both ends of the snubber circuit 2 are disposed on an opposite side to each other in the semiconductor chip CP. That is, the front surface electrode HE is disposed on a surface side of the semiconductor chip CP, and the back surface electrode BE is disposed on a back surface side of the semiconductor chip CP. Consequently, the plane dimension (plane area) of the semiconductor chip CP can be suppressed in comparison with a case of arranging both electrodes of both ends of the snubber circuit 2 on the surface side of the semiconductor chip, so that the manufacturing costs of the semiconductor chip CP including the snubber circuit 2 can be suppressed. In addition, the capacitive value of the capacitor 2a and the resistance value of the resistance 2b are easily controlled independently.

The present inventors have considered the semiconductor chip which has the front surface electrode and the back surface electrode located on the opposite side to each other and in which the snubber circuit is formed between the front surface electrode and the back surface electrode. As a result, the present inventors have found out that the structure of the above semiconductor chip CP is excellent. Hereinafter, such a point will be specifically explained.

In the semiconductor chip CP of the present embodiment, the polysilicon electrode PE is embedded in the trench TR1 via the insulating film CZ. Consequently, since an effective electrode area of the capacitor 2a can be increased, the capacitive value of the capacitor 2a can be efficiently increased.

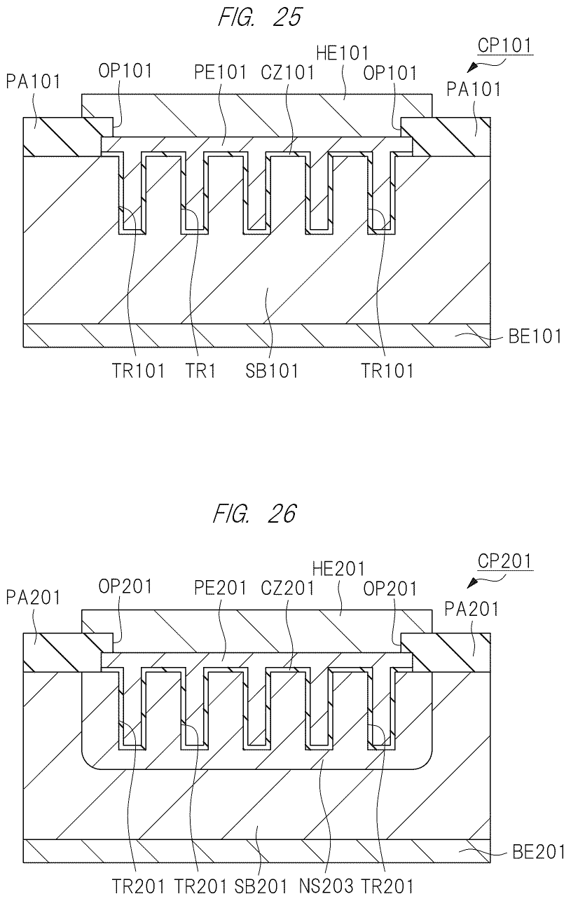

FIG. 25 is a cross-sectional view of a semiconductor chip CP101 of a first consideration example considered by the present inventors, and corresponds to FIG. 3.

In the semiconductor chip CP101 of the first consideration shown by FIG. 25, a trench TR101 is formed in a main surface of an n-type semiconductor substrate SB101 having nearly uniform n-type impurity concentrations, an insulating film CZ101 is formed on each of the main surface of the n-type semiconductor substrate SB101 and an inner surface of the trench TR101, and a polysilicon electrode PE101 is formed on the insulating film CZ101 so as to embed an inside of the trench TR101. A front surface electrode HE101 made of metal is formed on a polysilicon electrode PE101 exposed from an opening OP101 of an insulating film PA101, and a back surface electrode BE101 made of metal is formed on a back surface of the n-type semiconductor substrate SB101.

In a case of the semiconductor chip CP101 of the first consideration shown by FIG. 25, the above capacitor 2a is formed by a polysilicon electrode PE101, the n-type semiconductor substrate SB101, and the insulating film CZ101, and the above resistance 2b is formed by the n-type semiconductor substrate SB101. In this case, to increase the capacitive value of the capacitor 2a, the n-type impurity concentration of the n-type semiconductor substrate SB101 needs to be increased. This is because: when the n-type impurity concentration of the n-type semiconductor substrate SB101 is low, the depletion layer easily spreads in the n-type semiconductor substrate SB101, so that the capacitive value of the capacitor 2a becomes small; and because when the n-type impurity concentration of the n-type semiconductor substrate SB101 is high, the depletion layer is difficult to spread in the n-type semiconductor substrate SB101, so that the capacitive value of the capacitor 2a becomes large.

However, when the n-type impurity concentration of the n-type semiconductor SB101 is substrate high, the resistivity of the n-type semiconductor substrate SB101 becomes small, so that the resistance value of the resistance 2b becomes small. That is, when the n-type impurity concentration of the n-type semiconductor substrate SB101 is high, the capacitive value of the capacitor 2a increases, but the resistance value of the resistance 2b becomes small, while when the n-type impurity concentration of the n-type semiconductor substrate SB101 is low, the resistance value of the resistance 2b become large, but the capacitive value of the capacitor 2a becomes small. Accordingly, in the case of the semiconductor chip CP101 of the first consideration example shown by FIG. 25, optimizing both of the capacitive value of capacitor 2a and the resistance value of the resistance 2b is more difficult than the semiconductor chip CP of the present embodiment.

FIG. 26 is a cross-sectional view of a semiconductor chip CP201 of a second consideration example considered by the present inventors, and corresponds to FIG. 3 and FIG. 25.

In the semiconductor chip CP201 of the second consideration example shown FIG. 26, an n-type semiconductor substrate NS203 having an n-type impurity concentration higher than the n-type semiconductor substrate SB201 is formed into the n-type semiconductor substrate SB201 from the main surface of the n-type semiconductor substrate SB201. Then, a trench TR201 is formed in the n-type semiconductor region NB203, an insulating film CZ201 is formed on each of the main surface of the n-type semiconductor substrate SB201 and an inner surface of the trench TR201, and a polysilicon electrode PE201 is formed on the insulating film CZ201 so as to embed an inside of the trench TR201. A front surface electrode HE201 made of metal is formed on the polysilicon electrode PE201 exposed from an opening OP201 of the insulating film PA201, and a back surface electrode BE201 made of metal is formed on a back surface of the n-type semiconductor substrate SB201.

In the semiconductor chip CP201 of the second consideration example shown by FIG. 26, the above capacitor 2a is formed by the polysilicon electrode PE201, the n-type semiconductor region NS203, and the insulating film CZ201, and the above resistance 2b is formed by the n-type semiconductor region NS203 and the n-type semiconductor substrate SB201 under the n-type semiconductor region NS203. At this case, by increasing the n-type impurity concentration of the n-type impurity region NS203, the capacitive value of the capacitor 2a can be increased.

However, when the n-type impurity concentration of the n-type semiconductor substrate SB201 is low, connection between the back surface electrode BE201 and the n-type semiconductor substrate SB201 becomes Schottky connection. If the connection of the back surface electrode BE201 and the n-type semiconductor substrate SB201 becomes the Schottky connection, the resistance value of the resistance 2b is mainly determined by the Schottky connection between the back surface electrode BE201 and the n-type semiconductor substrate SB201, so that the resistance value of the resistance 2b easily fluctuates and it is difficult to obtain the resistance value as designed. Therefore, the Schottky connection is desirably prevented from being formed between the back surface electrode BE201 and the front surface electrode HE201. Meanwhile, when the n-type impurity concentration of the n-type semiconductor substrate SB201 is high, the connection between the back surface electrode BE201 and the n-type semiconductor substrate SB201 becomes ohmic connection and the resistance value of the resistance 2b is mainly determined by the n-type semiconductor substrate SB201, but the resistivity of the n-type semiconductor substrate SB201 becomes low, so that the resistance value of the resistance 2b becomes small.

That is, when the n-type impurity concentration of the n-type semiconductor substrate SB201 is low, the Schottky connection is formed between the back surface electrode BE201 and the n-type semiconductor substrate SB201, so that the resistance value of the resistance 2b easily fluctuates, while when the n-type impurity concentration of the n-type semiconductor substrate SB201 is high, the connection between the back surface electrode BE201 and the n-type semiconductor substrate SB201 becomes the ohmic connection, but the resistance value of the resistance 2b becomes small. Accordingly, in the case of the semiconductor chip CP of the second consideration example shown by FIG. 26, realizing both of the increase in the resistance value of the resistance 2b and the suppression of the fluctuation of the resistance value of the resistance 2b is more difficult than the semiconductor chip CP of the present embodiment. Therefore, it is difficult to form the capacitor 2a having the optimum capacitive value and the resistance 2b having the optimum resistance value in the semiconductor chip CP201 of the second consideration example shown by FIG. 26.

In contrast, the semiconductor chip CP of the present embodiment has the n-type semiconductor layer NS1, the n-type semiconductor layer NS2 formed on the upper surface of the n-type semiconductor layer NS1, and the n-type semiconductor region NS3 formed into the n-type semiconductor layer NS2 from the upper surface of the n-type semiconductor layer NS2. The n-type impurity concentration of the n-type semiconductor layer NS2 (n-type semiconductor region NS2a) located between the n-type semiconductor region NS3 and the n-type semiconductor layer NS1 is lower than an impurity concentration of each of the n-type semiconductor region NS3 and the n-type semiconductor layer NS1. Then, the trench TR1 is formed in the n-type semiconductor region NS3, the insulating film CZ is formed on each of the upper surface of the n-type semiconductor layer NS2 and the inner surface of the trench TR1, and the polysilicon electrode PE is formed on the insulating film CZ so as to embed the inside of the trench TR1. The front surface electrode HE made of metal is formed on the polysilicon electrode PE exposed from the opening OP1 of the insulating film PA, and the back surface electrode BE made of metal is formed on the lower surface of the n-type semiconductor layer NS1.

At the case of the semiconductor chip CP of the present embodiment, the above capacitor 2a is formed by the polysilicon electrode PE, the n-type semiconductor region NS3, and the insulating film CZ, and the above resistance 2b is formed by the n-type semiconductor region NS, the n-type semiconductor layer NS2 (n-type semiconductor region NS2a) under the n-type semiconductor region NS3, and the n-type semiconductor layer NS.

By increasing the n-type impurity concentration of the n-type semiconductor region NS3, the capacitive value of the capacitor 2a can be increased. In addition, by increasing the n-type impurity concentration of the n-type semiconductor layer NS1, the Schottky connection is prevented from being formed between the back surface electrode BE and the n-type semiconductor layer NS1, and the connection between the back surface electrode BE and the n-type semiconductor layer NS1 can be made the ohmic connection. As a result, the fluctuation of the resistance value of the resistance 2b can be suppressed. Then, by decreasing the impurity concentration of the n-type semiconductor layer NS2 (n-type semiconductor region NS2a) located between the n-type semiconductor region NS3 and the n-type semiconductor layer NS1, the resistivity of the n-type semiconductor layer NS2 (n-type semiconductor region NS2a) located between the n-type semiconductor region NS3 and the n-type semiconductor layer NS1 can be increased, thereby making it possible to increase the resistance value of the resistance 2b.

Namely, in order to increase the capacitive value of the capacitor 2a, it is desirable to increase the n-type impurity concentration of the n-type semiconductor region NS3; in order to prevent the Schottky connection from being formed between the back surface electrode BE and the n-type semiconductor layer NS1, it is desirable to increase the n-type impurity concentration of the n-type semiconductor layer NS1; and in order to increase the resistance value of the resistance 2b, it is desirable to decrease the n-type impurity concentration of the n-type semiconductor region NS2a. Based on this technical idea, in the present embodiment, the n-type impurity concentration of the n-type semiconductor layer NS2 (n-type semiconductor region NS2a) between the n-type semiconductor region NS3 and the n-type semiconductor layer NS1 is made lower than each n-type impurity concentration of the n-type semiconductor region NS3 and the n-type semiconductor layer NS1. Consequently, it can be realized to increase the capacitive value of the capacitor 2a, to suppress the fluctuation of the resistance value of the resistance 2b by preventing the Schottky connection from being formed between the back surface electrode BE and the n-type semiconductor layer NS1, and to increase the resistance value of the resistance 2b. As a result, the capacitor 2a having the optimum capacitive value and the resistance 2b having the optimum resistance value can be formed in the semiconductor chip CP. Thus, the performance of the semiconductor chip CP and the performance of the semiconductor package PKG using the semiconductor chip CP can be improved.

In addition, the capacitive value of the capacitor 2a and the resistance value of the resistance 2b can be controlled independently, so that the semiconductor chip CP having electric characteristics (capacitive value, resistance value) as designed is easily manufactured. Therefore, management of the manufacturing steps of the semiconductor chip CP becomes easy.

The n-type impurity concentration of the n-type semiconductor layer NS1 can be set at, for example, about 1E16/cm³. The n-type impurity concentration of the n-type semiconductor region NS2a can be set at, for example, about 1E20/cm³. The n-type impurity concentration of the n-type semiconductor region NS3 can be set at, for example, about 1E20 cm³.

In addition, a distance L1 (see FIG. 3) from an outer circumference (outer circumference side surface) of the n-type semiconductor region NS3 to an outer circumference (outer circumference side surface) of the n-type semiconductor layer NS2 in plan view is preferably larger than a distance L2 (see FIG. 3) from the bottom surface (lower surface) of the n-type semiconductor region NS3 to the upper surface of the n-type semiconductor layer NS1 (that is, L1>L2). Consequently, a leakage current passing through the outer circumference side surface of the semiconductor chip CP can be prevented from occurring.

In addition, in the present embodiment, the electrodes (here, front surface electrode HE and back surface electrode BE) of the both ends of the snubber circuit 2 are disposed on the opposite side to each other in the semiconductor chip CP. Therefore, as shown in FIG. 23 and FIG. 24, if the semiconductor chip CP is disposed on the pad BPC (source electrode SE) of the power semiconductor chip PC via the bonding material BD2 having conductivity, one of the front surface electrode HE and the back surface electrode BE can be electrically connected to the source electrode SE of the power semiconductor chip PC. Then, the other of the front surface electrode HE and the back surface electrode BE can be electrically connected to the back surface electrode RE for the drain of the power semiconductor chip PC via the wire BWC, the die pad DP, and the bonding material BD1 having conductivity. Therefore, the parallel connection of the power MOSFET 1 formed in the power semiconductor chip PC and the snubber circuit 2 formed in the semiconductor chip CP becomes easy.

### <Modified Example of Semiconductor Chip CP>

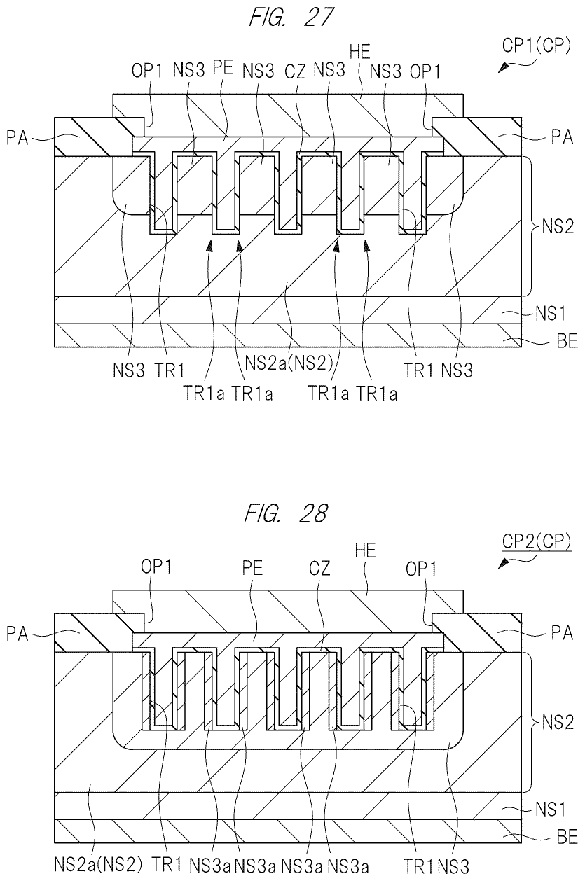

FIG. 27 is a cross-sectional view schematically showing a first modified example of the semiconductor chip CP of the present embodiment. FIG. 28 is a cross-sectional view schematically showing a second modified example of the semiconductor chip CP of the present embodiment. The semiconductor chip CP of the first modified example is called a semiconductor chip CP1. The semiconductor chip CP of the second modified example is called a semiconductor chip CP2.

A different point between the semiconductor chip CP1 of the first modified example shown by FIG. 27 and the semiconductor chip CP shown by FIG. 3 will be explained later.

In the semiconductor chip CP shown by FIG. 3, the trench TR1 is formed in the n-type semiconductor region NS3, and the depth of the bottom surface of the trench TR1 is shallower than the depth of the bottom surface of the n-type semiconductor region NS3. Therefore, the bottom surface and the side surface of the trench TR1 are covered with the n-type semiconductor region NS3, and the n-type semiconductor region NS3 exists under the bottom surface of the trench TR1. If it is looked another way, the trench TR1 does not penetrate through the n-type semiconductor region NS3 and does not reach the n-type semiconductor region NS2a.

In the semiconductor chip CP1 shown by FIG. 27, the trench TR1 is formed in the n-type semiconductor region NS3 and the n-type semiconductor region NS2a, and the depth of the bottom surface of the trench TR1 is deeper than the depth of the bottom surface of the n-type semiconductor region NS3 and is shallower than the depth of the upper surface of the n-type semiconductor layer NS1. Therefore, a side-surface upper portion of the trench TR1 is covered with the n-type semiconductor region NS3, but a side-surface lower portion and the bottom surface of the trench TR1 are covered with the n-type semiconductor region NS2a. If it is looked another way, the trench TR1 penetrates through the n-type semiconductor region NS3 reaches and the n-type semiconductor region NS3. Therefore, a corner portion TR1a of the trench is TR1 covered with not the n-type semiconductor region NS3 but the n-type semiconductor region NS2a. Here, the corner portion TR1a of the trench TR1 corresponds to a corner portion at which the side surface and the bottom surface of the trench TR1 intersect with each other.

Therefore, in a case in which the semiconductor chip CP1 shown by FIG. 27 is manufactured, if the trench TR1 is formed as shown by FIG. 6 or FIG. 14, the trench TR1 penetrates through the n-type semiconductor region NS3 and the bottom surface of the trench TR1 is shallower than the bottom surface of the n-type semiconductor region NS3.

When a potential difference occurs between the front surface electrode HE and the back surface electrode BE, an electric field concentration is easily generated in the vicinity of a corner portion TR1a of the trench TR1. In the semiconductor chip CP shown by FIG. 27, the corner portion TR1a of the trench TR1 is covered with not the n-type semiconductor region NS3 but the n-type semiconductor region NS2a having the n-type impurity concentration lower than that of the n-type semiconductor region NS3, so that the electric field concentration in the vicinity of the corner portion TR1a of the trench TR1 can be relieved. As a result, withstand voltage of the semiconductor chip CP1 can be improved.

Meanwhile, in the semiconductor chip CP shown by FIG. 3, the entire trench TR1 is covered with the n-type semiconductor region NS3 having an n-type impurity concentration higher than that of the n-type semiconductor region NS2a, so that the capacitive value of the capacitor 2a can be efficiently increased.

A different point between a semiconductor chip CP2 of the second modified example shown by FIG. 28 and the semiconductor chip CP shown by FIG. 3 will be explained later.

In the semiconductor chip CP2 shown by FIG. 28, an n-type semiconductor region NS3a is formed in the n-type semiconductor layer NS2 (more specifically, in the n-type semiconductor region NS3) along the side surface of the trench TR1. An n-type impurity concentration of the n-type semiconductor region NS3a is higher than the n-type impurity concentration of the n-type semiconductor region NS3.

The n-type semiconductor region NS3a can be formed, for example, by using an oblique ion implantation to implant n-type impurities into the semiconductor substrate SB1 from the side surface of the trench TR1 after forming the trench TR1 as shown by FIG. 6 or FIG. 14 and before forming the insulating film CZ.

In the semiconductor chip CP2 shown by FIG. 28, since the n-type semiconductor region NS3a having an n-type impurity concentration higher than that of the n-type semiconductor region NS3 is formed, the capacitive value of the capacitor 2a can be further increased.

Meanwhile, in the semiconductor chip CP shown by FIG. 3, an oblique ion implantation step for forming the n-type semiconductor region NS3a is unnecessary, so that the number of manufacturing steps of the semiconductor chip CP can be suppressed.

### Second Embodiment

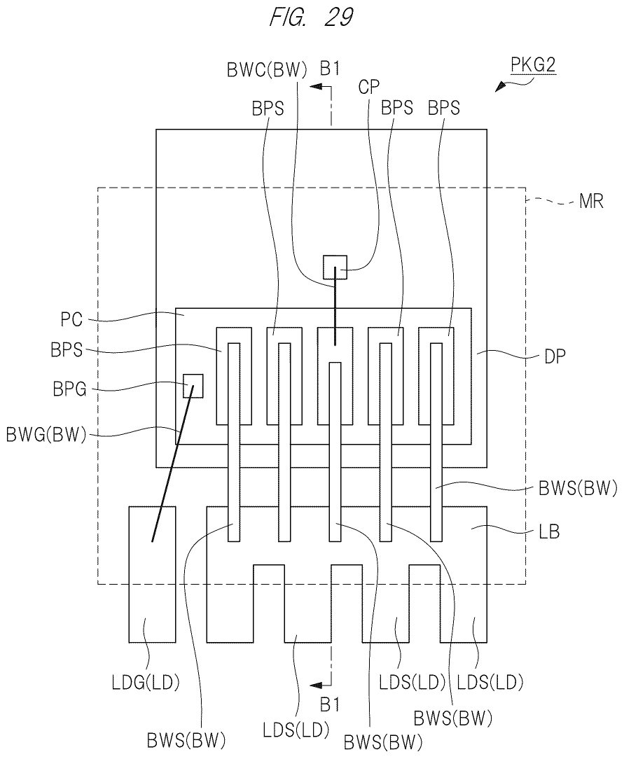

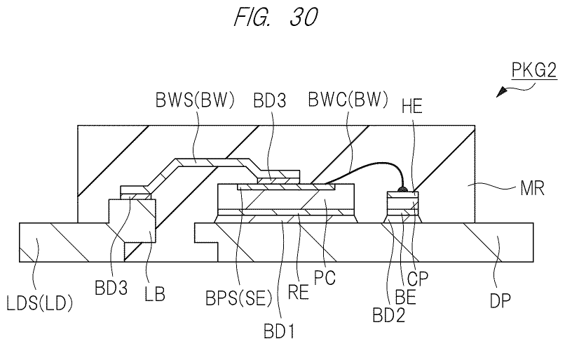

FIG. 29 is a plan perspective view showing a semiconductor package (semiconductor device, electronic device) PKG2 of a second embodiment. FIG. 30 is a cross-sectional view of the semiconductor package PKG2. FIG. 30 corresponds to the cross-sectional view taken along B1-B1 line of FIG. 29.

A different point between the semiconductor package PKG2 of the second embodiment and the semiconductor package PKG of the above first embodiment will be explained later.

In the semiconductor package PKG of the first embodiment, the semiconductor chip CP is mounted on the pad BPC (source electrode SE) of the semiconductor chip PC via the bonding material BD2 having conductivity.

In the semiconductor package PKG of the second embodiment, as shown FIG. 29 and FIG. 30, the semiconductor chip CP is disposed on the upper surface of the die pad DP via the bonding material BD2 having conductivity. That is, the power semiconductor chip PC and the semiconductor chip CP are disposed on the upper surface of the die pad DP, and the power semiconductor chip PC and the semiconductor chip CP do not overlap with each other in plan view.

In a case of FIG. 30, the semiconductor chip CP is disposed on the upper surface of the die pad DP via the boding material BD2 having conductivity such that the back surface electrode BE of the semiconductor chip CP opposes the upper surface of the die pad DP via the bonding material BD2. Therefore, the back surface electrode BE of the semiconductor chip CP is electrically connected to the die pad DP via the bonding material BD2 having conductivity, and is further electrically connected to the back surface electrode RE of the power semiconductor chip PC via the die pad DP and the bonding material BD1 having conductivity. Since the semiconductor chip CP is not mounted on the power semiconductor chip PC, the pad BPC for mounting the semiconductor chip CP does not need to be provided in the power semiconductor chip PC.

The front surface electrode HE of the semiconductor chip CP is electrically connected to the source pad BPS (source electrode SE) of the power semiconductor chip PC via the wire BWC. Specifically, one end portion of the wire BWC is connected to the front surface electrode HE of the semiconductor chip CP, and the other end portion of the wire BWC is connected to the source pad BPS (source electrode SE) of the power semiconductor chip CP.

Therefore, in the case of FIG. 30, the back surface electrode BE of the semiconductor chip CP is electrically connected to the drain of the power MOSFET 1 formed in the power semiconductor chip PC via the die pad DP, the bonding material BD1 having conductivity, and the back surface electrode RE of the power semiconductor chip PC. Then, the front surface electrode HE of the semiconductor chip CP is electrically connected to the source of the power MOSFET 1 formed in the power semiconductor chip PC via the wire BWC, the source pad BPS (source electrode SE) of the power semiconductor chip PC. Consequently, as shown in FIG. 1, the power MOSFET 1 formed in the power semiconductor chip PC and the snubber circuit 2 formed in the semiconductor chip CP are connected in parallel. That is, the case of FIG. 30 corresponds to the above circuit configuration of FIG. 1.

In the second embodiment, the semiconductor chip CP is disposed on not the power semiconductor chip PC but die pad DP. Therefore, when the wire BW is connected to the plurality of source pads BPS of the power semiconductor chip PC and the gate pad BPG, the semiconductor chip CP does not disturb the above connection. Accordingly, the wire bonding step is easily performed.

In the above first embodiment, the semiconductor chip CP is disposed on not the die pad DP but the power semiconductor chip PC. Therefore, the semiconductor package PKG is advantageous for miniaturization.

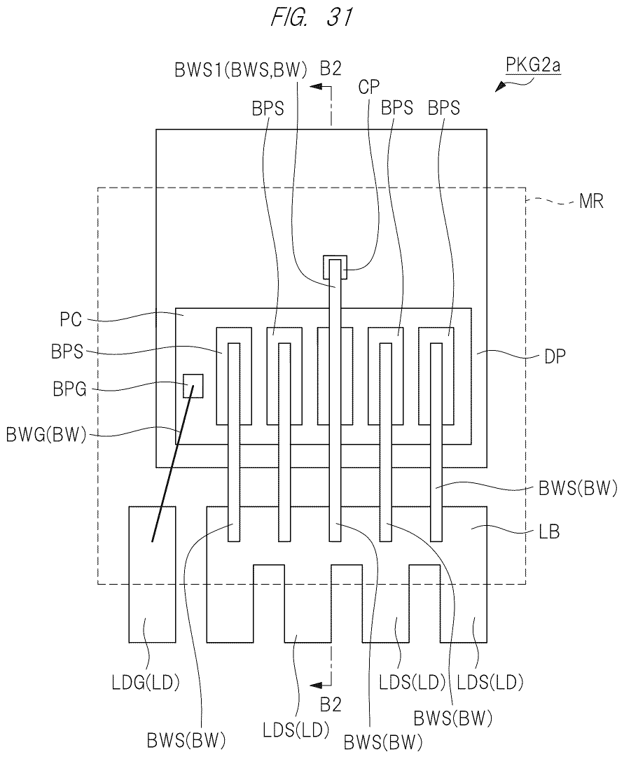

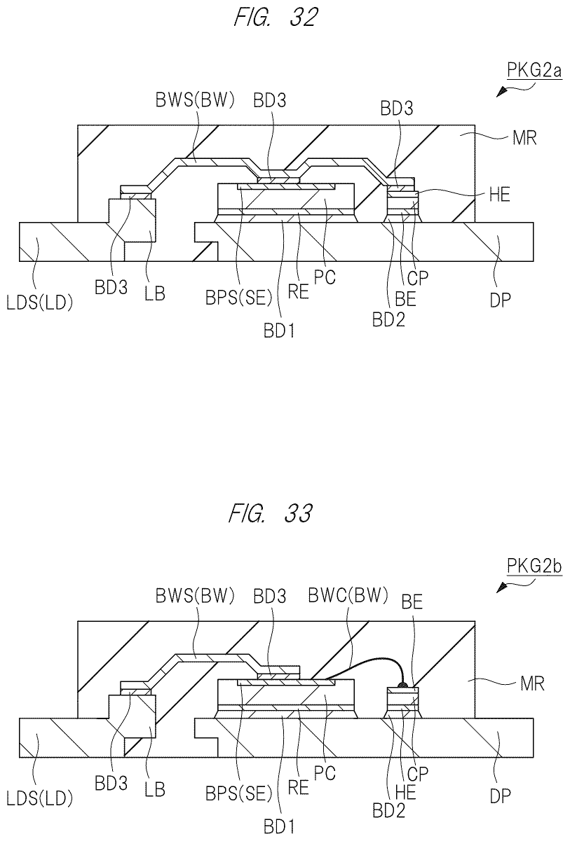

FIG. 31 is a plan perspective view showing a first modified example of the semiconductor package PKG2 of the second embodiment. FIG. 32 corresponds to a cross-sectional view taken along B2-B2 line of FIG. 31. The semiconductor package PKG2 of the first modified example is called a semiconductor package PKG2a.

A different point between the semiconductor package PKG2a shown by FIG. 31 and FIG. 32 and the semiconductor package PKG2 shown by FIG. 29 and FIG. 30 will be explained later.

In the semiconductor package PKG2a, as shown in FIG. 31 and FIG. 32, the front surface electrode HE of the semiconductor chip CP is electrically connected to the source pad BPS (source electrode SE) of the power semiconductor chip PC via a source wire BWS1 among the plurality of source wires BWS. Specifically, one end portion of the source wire BWS1 is connected to the lead coupling portion LB via the bonding material BD3 having conductivity such as solder, a center portion of the source wire BWS1 is connected to the source pad BPS (source electrode SE) of the power semiconductor chip PC via the bonding material BD3 having conductivity, and the other end portion of the source wire BWS1 is connected to the front surface electrode HE of the semiconductor chip CP via the bonding material BD3 having conductivity.

Therefore, in a case of FIG. 32, the back surface electrode BE of the semiconductor chip CP is electrically connected to the drain of the power MOSFET 1 formed in the power semiconductor chip PC via the die pad DP, the bonding material BD1 having conductivity, and the back surface electrode RE. Then, the front surface electrode HE of the semiconductor chip CP is electrically connected to the source of the power MOSFET 1 formed in the power semiconductor chip PC via the source wire BWS1, the source pad BPS (source electrode SE) of the power semiconductor chip PC. Consequently, as shown in FIG. 1, the power MOSFET 1 formed in the power semiconductor chip PC and the snubber circuit 2 formed in the semiconductor chip CP are connected in parallel.

FIG. 33 is a cross-sectional view showing a second modified example of the semiconductor package PKG2 of the second embodiment. The semiconductor package PKG of the second modified example is called a semiconductor package PKG2b.

The semiconductor package PKG2b shown by FIG. 33 is different from the semiconductor package PKG2 shown by FIG. 30 in a direction of the semiconductor chip CP. A different point between the semiconductor package PKG2b shown by FIG. 33 and the semiconductor package PKG2 shown by FIG. 30 will be explained later.

As shown in FIG. 33, in the semiconductor package PKG2b, the semiconductor chip CP is disposed on the upper surface of the die pad DP via the bonding material BD2 having conductivity such that the front surface electrode HE of the semiconductor chip CP opposes the upper surface of the die pad DP via the bonding material BD2. Therefore, the front surface electrode HE of the semiconductor chip CP is electrically connected to the die pad DP via the bonding material BD2 and is further having conductivity, electrically connected to the back surface electrode RE of the power semiconductor chip PC via the die pad DP and the bonding material BD1 having conductivity. The back surface electrode BE of the semiconductor chip CP is electrically connected to the source pad BPS (source electrode SE) of the power semiconductor chip PC via the wire BWC. Specifically, one end portion of the wire BWC is connected to the back surface electrode BE of the semiconductor chip CP, and the other end portion of the wire BWC is connected to the source pad BPS (source electrode SE) of the power semiconductor chip PC.

Therefore, in a case of FIG. 33, the front surface electrode HE of the semiconductor chip CP is electrically connected to the drain of the power MOSFET 1 formed in the power semiconductor chip PC via the die pad DP, the bonding material BD1 having conductivity, and the back surface electrode RE. Then, the back surface electrode HE of the semiconductor chip CP is electrically connected to the source of the power MOSFET 1 formed in the power semiconductor chip PC via the wire BWC and the source pad BPS (source electrode SE) of the power semiconductor chip PC. Consequently, as shown in FIG. 2, the power MOSFET 1 formed in the power semiconductor chip PC and the snubber circuit 2 formed in the semiconductor chip CP are connected in parallel. That is, the case of FIG. 33 corresponds to the above circuit configuration of FIG. 2.

The semiconductor package PKG2a of the first modified example and the semiconductor package PKG2b of the second modified example can be also combined. At this case, in the semiconductor package PKG2a of the first modified example shown by FIG. 32, a top and a bottom of the semiconductor chip CP may be inverted. At this case, the front surface electrode HE of the semiconductor chip CP is electrically connected to the die pad DP via the bonding material BD2 having conductivity, and the back surface electrode BE of the semiconductor chip CP is electrically connected to the source pad BPS (source electrode SE) of the power semiconductor chip PC via the source wire BWS1.

### Third Embodiment

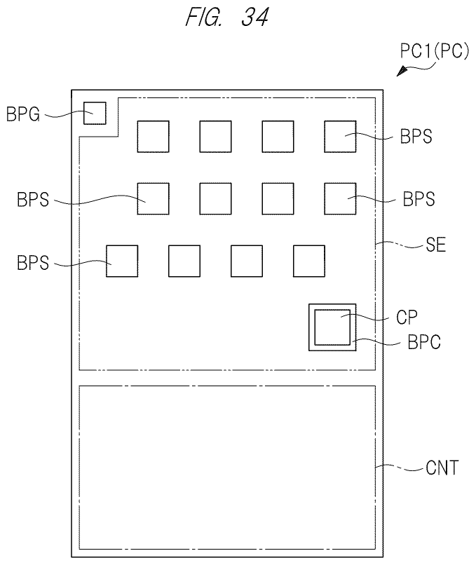

FIG. 34 is a plan view of a case of using an Intelligent Power Device (IPD) as the power semiconductor chip PC. The power semiconductor chip PC applying the IPD is called a power semiconductor chip PC1. FIG. 34 shows the source electrode SE by a dash-double-dot line, and shows a control circuit portion CNT by a dash-single-dot line. In the third embodiment, a different point between the first embodiment and the second embodiment will be explained later.

In the power semiconductor chip PC1 shown by FIG. 34, although not illustrated here, the power MOSFET 1 explained in the first embodiment and the control circuit portion CNT are formed. As explained with reference to FIG. 22, the power MOSFET 1 is formed by connecting in parallel the plurality of unit transistor cells Q1 formed on the semiconductor substrate configurating the power semiconductor chip PC1. The source electrode SE is formed so as to cover almost the entire transistor cell region in which the plurality of unit transistor cells Q1 are formed.

In FIG. 34, the semiconductor chip CP disposed on the power semiconductor chip PC1 are also shown. Since one of the front surface electrode HE and the back surface electrode BE of the semiconductor chip CP needs to be electrically connected to the source electrode SE of the power semiconductor chip PC1, the semiconductor chip CP is disposed at a position overlapping with the source electrode SE of the power semiconductor chip PC1 in plan view. That is, the semiconductor chip CP is disposed at a position overlapping with the transistor cell region in which the plurality of unit transistor cells Q1 are formed, but is disposed at a position not overlapping with the control circuit portion CNT.

As described above, the invention made by the present inventors have been specifically explained based on the embodiments, but the present invention is not limited to the above embodiments and, needless to say, can be variously modified within a range not departing from the gist thereof.

What is claimed is:

1. A semiconductor device comprising:
a first semiconductor layer of a first conductivity type, the first semiconductor layer having a first upper surface and a first lower surface opposite the first upper surface;
a second semiconductor layer of the first conductivity type, the second semiconductor layer being formed on the first upper surface of the first semiconductor layer;
a first semiconductor region of the first conductivity type, the first semiconductor region being formed into the second semiconductor layer from a second upper surface of the second semiconductor layer;
a trench formed in the first semiconductor region;
a first insulating film formed on each of the second upper surface of the second semiconductor layer, a bottom surface of the trench and a side surface of the trench;
a first electrode formed on the first insulating film so as to embed an inside of the trench;
a front surface electrode formed on the first electrode and electrically connected to the first electrode; and
a back surface electrode formed on the first lower surface of the first semiconductor layer and electrically connected to the first semiconductor layer,
wherein the first semiconductor region is formed in the second semiconductor layer such that a bottom surface of the first semiconductor region does not reach the first semiconductor layer in cross-sectional view,
wherein each of the front surface electrode and the back surface electrode is made of metal, and
wherein an impurity concentration of the second semiconductor layer located between the first semiconductor region and the first semiconductor layer is lower than an impurity concentration of each of the first semiconductor layer and the first semiconductor region.

2. The semiconductor device according to claim 1,
wherein the first electrode is made of polysilicon.

3. The semiconductor device according to claim 1,
wherein a bottom surface of the trench is shallower than the bottom surface of the first semiconductor region, and
wherein the bottom surface of the trench is covered with the first semiconductor region.

4. The semiconductor device according to claim 1,
wherein the bottom surface of the trench is deeper than the bottom surface of the first semiconductor region, and
wherein the trench penetrates through the first semiconductor region.

5. The semiconductor device according to claim 1,
wherein a second semiconductor region of the first conductivity type is formed in the first semiconductor region along the side surface of the trench, and
wherein an impurity concentration of the second semiconductor region higher is than the impurity concentration of the first semiconductor region.

6. The semiconductor device according to claim 1,
wherein a distance from an outer circumference of the first semiconductor region to an outer circumference of the second semiconductor layer in plan view is larger than a distance from the bottom surface of the first semiconductor region to the first upper surface of the first semiconductor layer.

7. The semiconductor device according to claim 1,
wherein a capacitive element is formed by the front surface electrode, the first insulating film, and the first semiconductor region.

8. The semiconductor device according to claim 7,
wherein the capacitive element is a capacitive element configurating a snubber circuit.

9. A method of manufacturing a semiconductor device, the method comprising:
(a) preparing a semiconductor substrate of a first conductivity type, the semiconductor substrate having a main surface and a back surface opposite the main surface;
(b) forming a first semiconductor region of the first conductivity type into the semiconductor substrate from the main surface of the semiconductor substrate;
(c) forming a trench in the first semiconductor region;
(d) forming a first insulating film on each of the main surface of the semiconductor substrate, a bottom surface of the trench and a side surface of the trench;
(e) forming a first electrode on the first insulating film so as to embed an inside of the trench;
(f) forming a front surface electrode on the first electrode, the front surface electrode being electrically connected to the first electrode;
(g) forming a first semiconductor layer of the first conductivity type into the semiconductor substrate from the back surface of the semiconductor substrate; and
(h) after the (g), forming a back surface electrode on the back surface of the semiconductor substrate,
wherein the first semiconductor layer has a lower surface aligning with the bottom surface, and an upper surface opposite the lower surface,
wherein a bottom surface of the first semiconductor region does not reach the first semiconductor layer,
wherein each of the front surface electrode and the back surface electrode is made of metal, and
wherein an impurity concentration of each of the first semiconductor layer and the first semiconductor region is higher than an impurity concentration of the semiconductor substrate.

10. The method according to claim 9,
wherein the first electrode is made of polysilicon.

11. The method according to claim 9,
wherein the bottom surface of the trench is shallower than a bottom surface of the semiconductor region.

12. The method according to claim 9,
wherein the bottom surface of the trench is deeper than a bottom surface of the semiconductor region.

13. The method according to claim 9, further comprising: (c1) before the (d) and after the (C), forming a second semiconductor region of the first conductivity type in the semiconductor substrate along the side surface of the trench by an oblique ion implantation,
wherein an impurity concentration of the second semiconductor region is higher than an impurity concentration of the first semiconductor region.

14. A semiconductor device comprising:
a chip mounting portion;
a first semiconductor chip disposed on the chip mounting portion via a first bonding material having conductivity and including a power MOSFET; and
a second semiconductor chip disposed on the first semiconductor chip via a second bonding material having conductivity,
wherein the first semiconductor chip has a source electrode, and a back surface electrode formed on opposite side of the source electrode,
wherein the back surface electrode of the first semiconductor chip is electrically connected to the chip mounting portion via the first bonding material,
wherein the second semiconductor chip has:
a first semiconductor layer of a first conductivity type, the first semiconductor layer having a first upper surface and a lower surface opposite the upper surface;
a second semiconductor region of the first conductivity type, the second semiconductor region being formed on the first upper surface of the first semiconductor layer;
a first semiconductor region of the first conductivity type, the first semiconductor region being formed into the second semiconductor layer from a second upper surface of the second semiconductor layer;
a trench formed in the first semiconductor region;
a first insulating film formed on each of the second upper surface of the second semiconductor layer, a bottom surface of the trench and a side surface of the trench;
a first electrode formed on the first insulating film so as to embed an inside of the trench;
a front surface electrode formed on the first electrode and electrically connected to the first electrode; and
a back surface electrode formed on the first lower surface of the first semiconductor layer and electrically connected to the first semiconductor layer,
wherein the first semiconductor region is formed in the second semiconductor layer such that the bottom surface of the first semiconductor region does not reach the first semiconductor layer in cross-sectional view,
wherein each of the front surface electrode and the back surface electrode of the second semiconductor chip is made of metal,
wherein an impurity concentration of the second semiconductor layer located between the first semiconductor region and the first semiconductor layer is lower than an impurity concentration of each of the first semiconductor layer and the first semiconductor region,
wherein the second semiconductor chip is disposed on the source electrode of the first semiconductor chip via the second bonding material, and
wherein one of the front surface electrode and the back surface electrode of the second semiconductor chip is electrically connected to the source electrode of the first semiconductor chip via the second bonding material.

15. The semiconductor chip according to claim 14, further comprising a conductive connection member electrically connecting the chip mounting portion and an other of the front surface electrode and the back surface electrode of the second semiconductor chip.

16. The semiconductor device according to claim 15,
wherein a capacitive element is formed by the front surface electrode, the first insulating film, and the first semiconductor region.

17. The semiconductor device according to claim 16,
wherein the capacitive element is a capacitive element configurating a snubber circuit.

18. The semiconductor device according to claim 14,
wherein the first electrode is made of polysilicon.

19. The semiconductor device according to claim 14,
wherein the bottom surface of the trench is shallower than a bottom surface of the first semiconductor region, and
wherein the bottom surface of the trench is covered with the first semiconductor region.

20. The semiconductor device according to claim 14,
wherein the bottom surface of the trench is deeper than a bottom surface of the first semiconductor region, and
wherein the trench penetrates through the first semiconductor region.
